(19) United States
(12) Patent Application Publication
(10) Pub. No.: US 2023/0343401 A1
(43) Pub. Date: Oct. 26, 2023

(54) NONVOLATILE MEMORY DEVICE, MEMORY SYSTEM, AND PROGRAMMING METHOD

(71) Applicant: YANGTZE MEMORY TECHNOLOGIES CO., LTD., Wuhan (CN)

(72) Inventors: Xueqing Huang, Wuhan (CN); Tianyu Wang, Wuhan (CN)

(21) Appl. No.: 17/954,913

(22) Filed: Sep. 28, 2022

(30) Foreign Application Priority Data
Apr. 25, 2022 (CN) 202210444080.4

(51) Int. Cl. G11C 16/34; G11C 16/10

(52) U.S. Cl. CPC G11C 16/3459; G11C 16/102; G11C 16/3495

(57) ABSTRACT

A nonvolatile memory device, a memory system, and a programming method are provided. The nonvolatile memory device includes a plurality of pages, and each of the pages includes a plurality of single-level cells. The programming method includes performing a programming operation on a first page of the plurality of pages using a signal including a first programming pulse, a programming verifying pulse, and a second programming pulse, where the first programming pulse is a start programming pulse and the second signal value of the second programming pulse is greater than a first signal value of the first programming pulse; and programming a second page of the plurality of pages using only a third programming pulse, where a third signal value of the third programming pulse is determined based at least on the first signal value and the failed bit count.

### CROSS-REFERENCE TO RELATED APPLICATION

The present application claims the benefit of priority to China Application No. 202210444080.4, filed on Apr. 25, 2022, the content of which is incorporated herein by reference in its entirety.

### TECHNICAL FIELD

The present disclosure relates to the field of semiconductor technologies, and in particular, to a nonvolatile memory device, a memory system, and a programming method.

### BACKGROUND

NAND memories are widely used in various electronic products, such as mobile phones, computers, smart sensors, positioning apparatuses, and the like, due to their characteristics of data non-volatility, fast read and write speed, low power consumption, long service life, etc. As consumers have higher requirements for the performance and reliability of electronic products, there are higher requirements on the read/write speed, service life, and the like of NAND memories on the market. Three basic operations including erasing, writing (also known as programming), and reading are involved with respect to the NAND memories. Programming methods of the NAND memories in the prior art have excessively long programming time, leading to the slow writing speed of the memories, or suffer from excessive programming, which shortens the service life of the memories. These programming methods are undesirable, and are difficult to meet the market requirements for the overall performance of NAND memories.

### SUMMARY

In view of the above, embodiments of the present disclosure provide a nonvolatile memory device, a memory system, and a programming method.

According to a first aspect of the present disclosure, there is provided a programming method for a non-volatile memory device, the non-volatile memory device includes a plurality of pages, each of the pages includes a plurality of single-level cells, and the programming method includes: performing a programming operation on a first page of the plurality of pages using a signal including a first programming pulse, a programming verification pulse, and a second programming pulse, wherein the first programming pulse is a start programming pulse, and a second signal value of the second programming pulse is greater than a first signal value of the first programming pulse, and the programming verification pulse is used to obtain the failed bit count of the first page after application of the first programming pulse and before application of the second programming pulse; and performing a programming operation on a second page of the plurality of pages using only a third programming pulse, wherein a third signal value of the third programming pulse is determined based at least on the first signal value and the failed bit count.

According to a second aspect of the present disclosure, there is provided a non-volatile memory device including: an array of memory cells including a plurality of pages, each of the pages including a plurality of single-level cells; peripheral circuit coupled to the array of memory cells, the peripheral circuit being configured to: perform a programming operation on a first page of the plurality of pages using a signal including a first programming pulse, a programming verification pulse, and a second programming pulse, wherein the first programming pulse is a start programming pulse, and a second signal value of the second programming pulse is greater than a first signal value of the first programming pulse, and the programming verification pulse is used to obtain the failed bit count of the first page after application of the first programming pulse and before application of the second programming pulse; and perform a programming operation on a second page of the plurality of pages using only a third programming pulse, wherein a third signal value of the third programming pulse is determined based at least on the first signal value and the failed bit count.

According to a third aspect of the present disclosure, there is provided a memory system, including: one or more non-volatile memory devices according to the second aspect of the present disclosure; and a memory controller coupled to the non-volatile memory device and configured to control the non-volatile memory device.

### BRIEF DESCRIPTION OF THE DRAWINGS

FIG. 1 illustrates a block diagram of an exemplary system with a memory according to an embodiment of the present disclosure;

FIG. 2A and FIG. 2B illustrate block diagrams of memory systems according to an embodiment of the present disclosure;

FIG. 3 illustrates a schematic circuit diagram of a memory including a peripheral circuit according to an embodiment of the present disclosure;

FIG. 4 illustrates a schematic diagram of a peripheral circuit according to an embodiment of the present disclosure;

FIG. 5 illustrates the threshold voltage margin profile of pages with different P/E cycles obtained by DSLC programming;

FIG. 6 illustrates a schematic flowchart of a programming method for a nonvolatile memory device according to an embodiment of the present disclosure;

FIG. 7 illustrates a schematic flowchart of a programming method for a memory system according to an embodiment of the present disclosure;

FIG. 8 illustrates a threshold voltage profile of memory cells in a test page according to an embodiment of the present disclosure;

FIG. 9 illustrates a first correspondence between a programming pulse offset value and the failed bit count according to an embodiment of the present disclosure;

FIG. 10 illustrates a relationship diagram between a position of a page and a characteristic signal value of the page according to an embodiment of the present disclosure;

FIG. 11 illustrates a schematic flowchart of programming a block to be programmed according to an embodiment of the present disclosure;

FIG. 12 illustrates a threshold voltage profile of memory cells of two pages in block 234 according to an embodiment of the present disclosure;

FIG. 13 illustrates a threshold voltage profile of memory cells of two pages in block 80 according to an embodiment of the present disclosure;

FIG. 14 illustrates a threshold voltage profile of memory cells in a page after 100 P/E cycles of the page using the DSLC method and the programming method shown in FIG. 5;

FIG. 15 illustrates a cumulative profile of margins between erased state threshold voltages and specific voltages for pages of blocks 234 and 236; and

FIG. 16 illustrates a schematic flowchart of a method for fabricating a memory system according to an embodiment of the present disclosure.

### DETAILED DESCRIPTION

The technical solutions of the present disclosure will be further elaborated below with reference to the accompanying drawings and in conjunction with specific embodiments of the description. It should be understood that, throughout the descriptions of the present disclosure, the orientation or positional relationship indicated by the terms “length”, “width”, “depth”, “above”, “under”, “external”, and the like is based on the orientation or positional relationship shown in the drawings only for the convenience of describing the present disclosure and simplifying the description, rather than indicating or implying that the referred device or element must have a specific orientation, or be constructed and operated in a specific orientation, and therefore should not be construed as a limitation of the present disclosure.

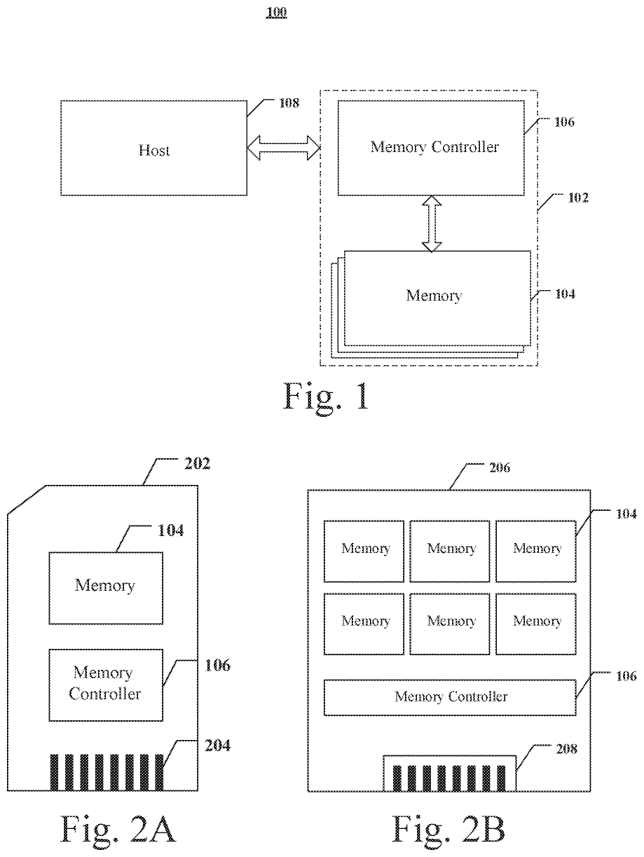

FIG. 1 is a block diagram of an exemplary system with memory according to an embodiment of the present disclosure. A system 100 may be a mobile phone, desktop computer, laptop computer, tablet computer, vehicle computer, game console, printer, pointing device, wearable electronic device, smart sensor, virtual reality (VR) device, augmented reality (AR) device, or any other suitable electronic device with storage therein. As shown in FIG. 1, the system 100 may include a host 108 and a memory system 102 having one or more memories 104 and a memory controller 106. The host 108 may be a processor (e.g., a central processing unit (CPU)) or a system on a chip (SoC) (e.g., an application processor (AP)) of the electronic device. The host 108 may be configured to send data to or receive data from the memory 104.

The memory 104 may be any type of memory in the present disclosure, e.g., a non-volatile memory device. The non-volatile memory device may be NAND flash memory (e.g., three-dimensional (3D) NAND flash memory).

In some embodiments, the memory controller 106 is coupled to the memory 104 and the host 108 and is configured to control the memory 104. The memory controller 106 may manage data stored in the memory 104 and communicate with the host 108. In some embodiments, the memory controller 106 is configured to perform the programming methods provided by the embodiments of the present disclosure to control the memory 104.

In some embodiments, the memory controller 106 is designed to operate in a low duty cycle environment, such as secure digital (SD) cards, compact flash (CF) cards, universal serial bus (USB) flash drives, or other medium for use in electronic devices such as personal calculators, digital cameras, mobile phones, etc.

In some embodiments, the memory controller 106 is designed to operate in a high duty cycle environment SSD or Embedded Multimedia Card (eMMC). SSD or eMMC functions as data storage and enterprise storage arrays for mobile devices such as smartphones, tablets, laptops, etc. The memory controller 106 may be configured to control operations of the memory 104, such as reading, erasing, and programming operations.

The memory controller 106 may also be configured to manage various functions with respect to data stored or to be stored in the memory 104 including, but not limited to, bad block management, garbage collection, logical to physical address translation, wear leveling, and the like.

In some embodiments, the memory controller 106 is also configured to process error correction codes (ECC) with respect to data read from or written to the memory 104. The memory controller 106 may also perform any other suitable functions, such as formatting the memory 104. The memory controller 106 may communicate with external devices (e.g., the host 108) according to a particular communication protocol. For example, the memory controller 106 may communicate with external devices through at least one of various interface protocols, such as USB protocol, MMC protocol, Peripheral Component Interconnect (PCI) protocol, PCI Express (PCIE) protocol, Advanced Technology Attachment (ATA) protocol, Serial ATA protocol, Parallel ATA protocol, Small Computer Small Interface (SCSI) protocol, Enhanced Small Disk Interface (ESDI) protocol, Integrated Drive Electronics (IDE) protocol, Firewire protocol, etc.

The memory controller 106 and the one or more memories 104 may be integrated into various types of storage devices, for example, being included in the same package (e.g., a Universal Flash Storage (UFS) package or an eMMC package). That is, memory system 102 can be implemented and packaged into different types of end electronic products.

In one embodiment as shown in FIG. 2A, the memory controller 106 and the single memory 104 may be integrated into the memory card 202. The memory card 202 may include a PC card (PCMCIA, Personal Computer Memory Card International Association), a CF card, a Smart Media (SM) card, a memory stick, a multimedia card (MMC, RS-MMC, MMCmicro), an SD card (SD, miniSD, microSD, SDHC), UFS, etc. The memory card 202 may also include a memory card connector 204 that couples the memory card 202 with a host (e.g., the host 108 in FIG. 1).

In another embodiment as shown in FIG. 2B, the memory controller 106 and multiple memories 104 may be integrated into the SSD 206. SSD 206 may also include an SSD connector 208 that couples SSD 206 with a host (e.g., the host 108 in FIG. 1). In some embodiments, the storage capacity and/or operating speed of SSD 206 is greater than that of the memory card 202.

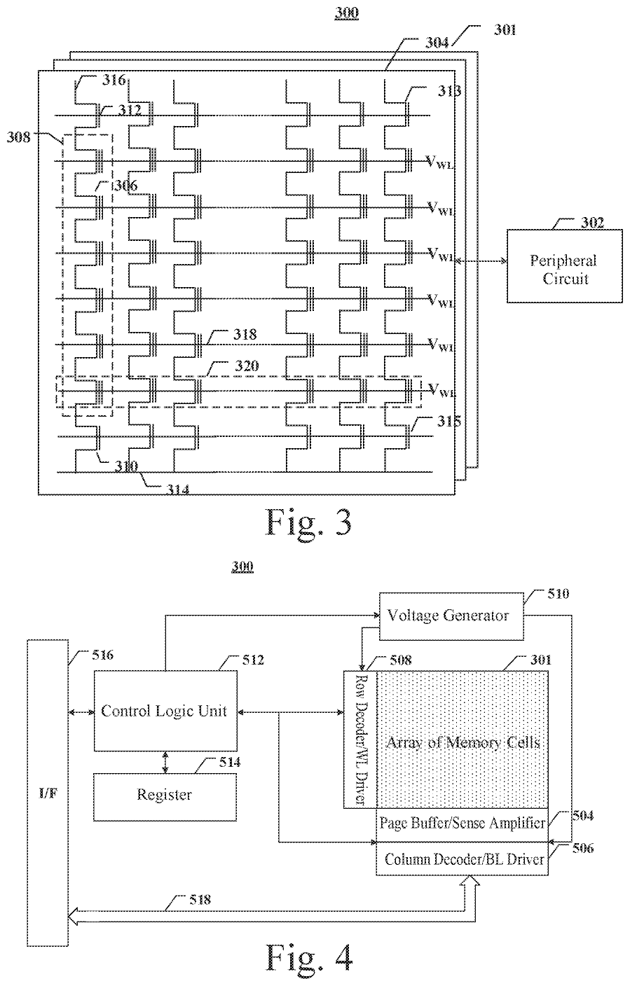

FIG. 3 illustrates a schematic circuit diagram of a memory 300 including peripheral circuits according to an embodiment of the present disclosure. The memory 300 may be an example of the memory 104 in FIG. 1. The memory 300 may include an array of memory cells 301 and a peripheral circuit 302 coupled to the array of memory cells 301. The array of memory cells 301 may be an array of NAND flash memory cells, where the memory cells 306 are provided in the form of an array of NAND memory strings 308, each NAND memory string 308 extending vertically above a substrate (not shown).

In some embodiments, the peripheral circuit 302 is configured to perform the programming methods according to the embodiments of the present disclosure. It can be understood that the peripheral circuit 302 may be configured to perform, according to the received instruction of the memory controller 106, the programming method according to the embodiments of the present disclosure.

In some embodiments, each NAND memory string 308 includes a plurality of memory cells 306 coupled in series and stacked vertically. Each memory cell 306 may hold a continuous analog value, e.g., a voltage or charge, depending on the number of electrons trapped within the area of the memory cell 306. Each memory cell 306 may be a floating gate type memory cell including a floating gate transistor, or a charge trap type memory cell including a charge trap transistor.

In some embodiments, each memory cell 306 is a single-level cell (SLC) that has two possible memory states and thus can store one bit of data. For example, a first memory state “0” may correspond to a first voltage range, and a second memory state “1” may correspond to a second voltage range. As shown in FIG. 3, each NAND memory string 308 may include a source select gate (SSG) 310 at its source terminal and a drain select gate (DSG) 312 at its drain terminal. SSG 310 and DSG 312 may be configured to activate selected NAND memory strings 308 (columns of the array) during reading and programming operations.

In some embodiments, the sources of the NAND memory strings 308 in the same block 304 are coupled by the same source line (SL) 314 (e.g., a common SL). In other words, according to some implementations, all NAND memory strings 308 in the same block 304 have an array common source (ACS). According to some implementations, the DSG 312 of each NAND memory string 308 is coupled to a corresponding bit line 316 from which data can be read or written via an output bus (not shown).

In some embodiments, each NAND memory string 308 is configured to be selected or deselected by applying a select voltage (e.g., higher than the threshold voltage of the transistor with DSG 312) or a deselect voltage (e.g., 0V) to the respective DSG 312 via one or more DSG lines 313 and/or by applying a select voltage (e.g., higher than the threshold voltage of the transistor with the SSG 310) or a deselect voltage (e.g., 0V) to the respective SSG 310 via one or more SSG lines 315.

As shown in FIG. 3, NAND memory strings 308 may be organized into multiple blocks 304, each of which may have a common source line 314 (e.g., coupled to ground). In some embodiments, each block 304 is the basic unit of data for an erase operation, i.e., all memory cells 306 on the same block 304 are erased simultaneously. To erase memory cells 306 in a selected block, an erase voltage (Vers) (e.g., a high positive voltage (e.g., 20V or higher)) can be bias coupled to source lines 314 of the selected block and of the unselected blocks that are on the same side as the selected block. It should be appreciated that in some examples, erase operations may be performed at the half-block level, at the quarter-block level, or at the level with any suitable number of blocks or any suitable fraction of blocks.

The memory cells 306 of adjacent NAND memory strings 308 may be coupled by word lines 318 that select which row of memory cells 306 is affected by reading and programming operations. In some embodiments, each word line 318 is coupled to a page 320 of memory cells 306, which is the basic unit of data used for programming operations. The size of a page 320 in bits may be related to the number of NAND memory strings 308 coupled by word lines 318 in a block 304. Each word line 318 may include a plurality of control gates (gate electrodes) at each memory cell 306 in the corresponding page 320 and a gate line that couples the control gates.

The peripheral circuit 302 may be coupled to the array of memory cells 301 via bit lines 316, word lines 318, source lines 314, SSG lines 315, and DSG lines 313. Peripheral circuit 302 may include any suitable analog, digital, and mixed-signal circuitry for facilitating the operation of the array of memory cells 301 by applying voltage and/or current signals to each target memory cell 306 and sensing voltage and/or current signals from each target memory cell 306 via bit lines 316, word lines 318, source lines 314, SSG lines 315, and DSG lines 313. The peripheral circuits 302 may include various types of peripheral circuits formed using metal-oxide-semiconductor (MOS) technology. For example, FIG. 4 is a schematic diagram of a peripheral circuit according to an embodiment of the present disclosure. The peripheral circuit 302 includes a page buffer/sense amplifier 504, a column decoder/bit line driver 506, a row decoder/word line driver 508, a voltage generator 510, a control logic unit 512, a register 514, an interface 516 and a data bus 518. It should be understood that in some examples, additional peripheral circuits not shown in FIG. 4 may also be included.

The page buffer/sense amplifier 504 may be configured to read data from and program (write) data to the array of memory cells 301 according to control signals from the control logic unit 512. In one example, the page buffer/sense amplifier 504 may store a page of programming data (write data) to be programmed into one page 320 of the array of memory cells 301. In another example, the page buffer/sense amplifier 504 may perform a program verify operation to ensure that data has been properly programmed into memory cells 306 coupled to selected word lines 318. In yet another example, the page buffer/sense amplifier 504 may also sense low power signals from bit lines 316 representing data bits stored in memory cells 306, and amplify small voltage swings to an identifiable logic level during read operations. The column decoder/bit line driver 506 may be configured to be controlled by the control logic unit 512 and to select one or more NAND memory strings 308 by applying bit line voltages generated from the voltage generator 510.

The row decoder/word line driver 508 may be configured to be controlled by the control logic unit 512, and to select/deselect the block 304 of the array of memory cells 301 and select/deselect word lines 318 of the block 304. The row decoder/word line driver 508 may also be configured to drive word lines 318 using word line voltages generated from the voltage generator 510. In some embodiments, the row decoder/word line driver 508 may also select/deselect and drive SSG line 315 and DSG line 313. As described in detail below, the row decoder/word line driver 508 is configured to perform erase operations on memory cells 306 coupled to the selected word line(s) 318. The voltage generator 510 may be configured to be controlled by the control logic unit 512 and to generate word line voltages (e.g., read voltages, programming voltages, pass voltages, local voltages, verification voltages, etc.), bit line voltage, and source line voltage to be supplied to the array of memory cells 301.

The control logic unit 512 may be coupled to each of the peripheral circuits described above and be configured to control the operation of each peripheral circuit. The register 514 may be coupled to control logic unit 512 and include status registers, command registers, and address registers for storing status information, command opcodes (OP codes), and command addresses for controlling the operation of each peripheral circuit. The interface 516 may be coupled to the control logic unit 512 and act as a control buffer to buffer and relay control commands received from a host (not shown) to control logic unit 512, and to buffer and relay status information received from control logic unit 512 to the host. The interface 516 may also be coupled to the column decoder/bit line driver 506 via the data bus 518, and act as a data I/O interface and data buffer to buffer and relay data to and from the array of memory cells 301.

In NAND flash memory, Single-level Cell (SLC) occupies a certain share in the memory market due to its advantages of fast read and write speed, high reliability and long service life, and the like.

Generally, Incremental Step-Pulse Programming (ISPP) can be used to perform write operations on the NAND flash memory. For NAND flash memory, write operations are performed in pages, each page including a plurality of memory cells arranged in an array.

In some embodiments, when programming is started, the first programming pulse is applied to the selected page in the memory first, and then programming verification is performed on the page to check whether the threshold voltage of each memory cell in the page reaches a target threshold voltage. If the number of memory cells not programmed to the target threshold voltage is greater than an allowable range, a second programming pulse with a higher voltage is then re-applied, and program verification is performed again after the application of the second programming pulse. The above process of applying programming pulses and performing programming verification is repeated until the number of memory cells not programmed to the target threshold voltage is within the allowable range, and the programming of the entire page ends.

To facilitate the evaluation of the number of memory cells in the page that have not been programmed to the target threshold voltage after a programming pulse is applied to the page, a failed bit count (FBC) is introduced, which refers to the number of bits in the page that have not been programmed to the target threshold voltage. In practical applications, it can be determined whether the programming is passed based on the relationship between the failed bit count and a target failed bit count during the programming verification.

For example, if the failed bit count of the page is greater than the target failed bit count (that is, the failed bit count of the page is not within the allowable range of the target failed bit count), then the next programming pulse with a higher voltage is re-applied, and programming verification is performed again after application of the next programming pulse. The above process of applying programming pulses and performing verification is repeated until the failed bit count of the page is less than or equal to the target failed bit count (that is, the failed bit count of the page is within the allowable range of the target failed bit count), and the programming of the entire page ends.

In some embodiments, the maximum number of applied programming pulses may be set. When the number of applied programming pulses is less than the maximum number, the above process of applying programming pulses and performing verification may be repeated until the failed bit count is less than or equal to the target failed bit count. When the number of applied programming pulses is equal to the maximum number, and the failed bit count is still greater than the target failed bit count, the programming of the page can be stopped, and the programming of the page is considered to fail.

It should be noted that the target threshold voltage is used to determine whether the memory cell reaches the programmed state. In some embodiments, when the threshold voltage of the memory cell is greater than or equal to the target threshold voltage, the memory cell reaches the programmed state. When the threshold voltage of the memory cell is less than the target threshold voltage, the memory cell has not reached the programmed state.

Taking a single-level cell SLC as an example, the single-level cell can store 1-bit data, including a programmed state or an erased state. The programmed state can be represented by “1”, and the erased state can be represented by “0”. In some embodiments, the programmed state may be represented by a “0” and the erased state may be represented by a “1”. For example, the erased state “1” corresponds to a first voltage range, and the programmed state “0” corresponds to a second voltage range. The write operation is performed by applying programming pulses to the memory cells to increase the threshold voltages of the memory cells from the first voltage range corresponding to the erased state to the second voltage range corresponding into the programmed state.

As mentioned above, the above programming method requires multiple applications of programming pulses, and after each application of the programming pulse, a verification voltage needs to be applied to verify the programming result of the page, so the programming time (Tprog) is long.

In the PCIE3.0 era, in order to shorten the programming time, a Dynamic Single-Level Cell (DSLC) mode has evolved. In DSLC mode, a page is programmed into the programmed state all at once by applying a large programming pulse to the page. Here, programming a page into the programmed state means making the failed bit count of the page less than or equal to the target failed bit count. This DSLC programming mode can shorten the programming time.

However, DSLC mode may cause the threshold voltages of the memory cells in the page to be much greater than the target threshold voltage (also called over-programming). As the Program/Erase cycles (i.e., P/E cycles) increase, over-programming can cause the threshold voltage of the programmed state of the memory cell to shift and the erased state to degrade, reducing the reliability of the NAND flash memory. Also, over-programming can also lead to a decrease in the endurance of the memory cells, which in turn leads to a decrease in the overall lifetime of the NAND flash memory. In NAND flash memory, the lifetime of the memory is generally characterized by P/E cycling. Using the DSLC programming method, the NAND memory has a P/E cycling of about three thousand (3k).

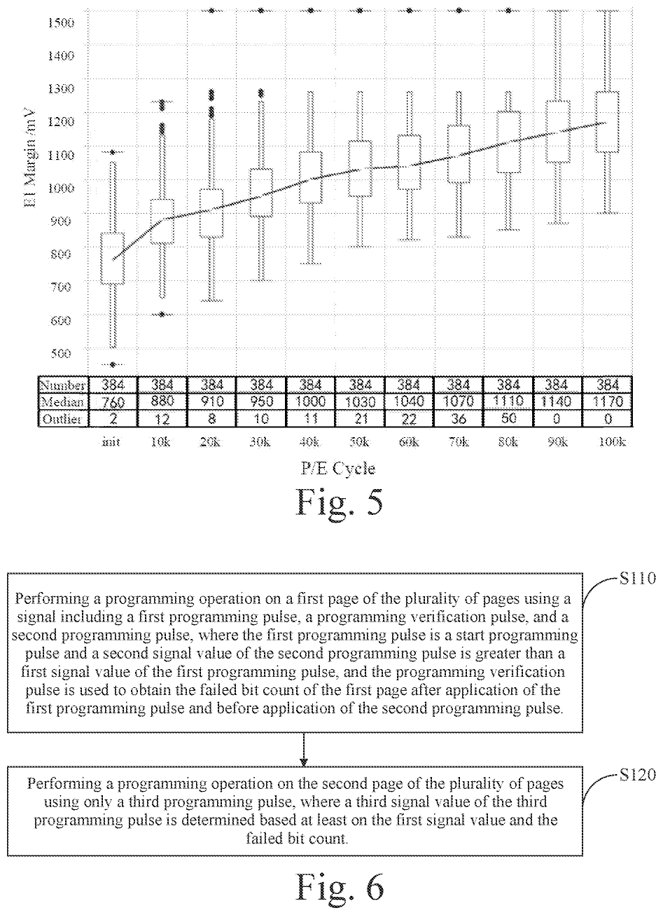

FIG. 5 illustrates a threshold voltage margin profile of pages with different P/E cycles obtained by using DSLC programming. In FIG. 5, the horizontal axis represents the P/E cycles, the vertical axis represents the threshold voltage margin for the programmed state (E1) (E1 margin), “quantity” refers to the number of pages, and “median” refers to the median of the threshold voltage margin for the programmed state of multiple pages. As shown in FIG. 5, as the P/E cycles increases from the initial number (init, for example, 0) to 100k, the median of the threshold voltage margin for the programmed state gradually increases. In particular, when the P/E cycles are increased to 100k, the median of the threshold voltage margin for the programmed state of the pages is increased by 410 mv compared to the median of the threshold voltage margin for the programmed state of the unerased pages (the pages whose P/E cycles are the initial number).

It can be seen from the analysis of FIG. 5, after the programming pulses at the same voltage are applied to the pages with different P/E cycles in the erasing state, the changes of the threshold voltages of the memory cells in the pages with different P/E cycles are different, and as the P/E cycles increase, the amount of increase in the threshold voltage of the memory cell is gradually increased. That is, as the P/E cycles increase, the degree of over-programming of the pages will gradually increase, and the lifespan of the memory will be shortened.

In order to make up for the problem of short service life and low reliability of the memory due to the disadvantage of over-programming in the DSLC mode, a High Program Erase Single-Level Cell (HPE SLC) mode is proposed. When programming in HPE SLC mode, two programming pulses are applied to the page successively. The signal value of the first programming pulse is smaller, so that the page is not programmed into the programmed state; then, the second programming pulse with a higher signal value is re-applied so that the page is programmed into the programmed state.

Compared to DSLC mode, although HPE SLC mode can reduce over-programming, improve the endurance of memory cells, and make the P/E factor of NAND flash memory reach 100k or 120k, however, two programming pulses are applied to each page in the HPE SLC mode, which prolongs the programming time. And, as the P/E cycles increase, the programming speed is getting faster and faster. When the P/E cycles reach several 10k, only one programming pulse is often needed to make the page programmed into the programmed state. In HPE SLC mode, two programming pulses are applied to the page, which will cause over-programming of the page when the P/E cycle reaches several 10k, resulting in a shift of the threshold voltage of the memory cells in the page in the programmed state and degradation of the erased state. In turn, the reliability of the memory is reduced and the service life is shortened.

It can be seen that the programming methods of ISPP, DSLC, and HPE SLC cannot make the memory offer the fine comprehensive performance of fast read and write speed, long service life, high reliability, and the like.

In view of this, the present disclosure proposes a programming method for a non-volatile memory device. FIG. 6 illustrates a method for programming a non-volatile memory device according to an embodiment of the present disclosure. The non-volatile memory device includes at least one block; the block includes a plurality of pages; and the pages include single-level cells. The method for programming the non-volatile memory device includes:
S110: performing a programming operation on a first page of the plurality of pages using a signal including a first programming pulse, a programming verification pulse, and a second programming pulse, where the first programming pulse is a start programming pulse, and a second signal value of the second programming pulse is greater than a first signal value of the first programming pulse, and the programming verification pulse is used to obtain the failed bit count of the first page after application of the first programming pulse and before application of the second programming pulse; and
S120: performing a programming operation on the second page of the plurality of pages using only a third programming pulse, where a third signal value of the third programming pulse is determined based at least on the first signal value and the failed bit count.

Here, the first page may be any page in the block. In some embodiments, a plurality of pages included in a block may be arranged in sequence in a stacked manner, and the first page may be the bottommost page in the block, or the first page may be the topmost page in the block.

The second page is another page in the block except for the first page. The number of second pages is greater than or equal to 2. Illustratively, a block includes 128 pages, of which the number of the first page is one and the number of the second pages is 127.

Here, the first programming pulse, the second programming pulse, and the third programming pulse may be one voltage pulse signal, or may be one current pulse signal. Correspondingly, the first signal value, the second signal value, and the third signal value may be a voltage value or a current value.

Here, the first programming pulse is the start programming pulse. For example, the start programming pulse may be the first programming pulse applied to the block after erasing the block. It can be understood that when programming the block, the start programming pulse is first applied to the first page. The second programming pulse is the second programming pulse applied to the first page. In some embodiments, the second signal value of the second programming pulse is greater than the first signal value of the first programming pulse, and after the second programming pulse is applied to the first page, the first page is programmed into the programmed state without over-programming.

The third programming pulse is the only programming pulse applied to the second page after erasing the block and before the next erasing of the block. After the third programming pulse is applied to the second page, the second page is programmed into the programmed state without over-programming.

In some embodiments, the signal value of the programming verification pulse may be equal to the target threshold voltage of the single-level cells to verify whether each single-level cell in the first page is programmed to reach the target threshold voltage.

As shown in FIG. 5, in the DSLC mode, when programming pulses with the same signal value are applied to pages with different P/E cycles, all pages are programmed into the programmed state, and pages with more P/E cycles will be over-programmed. Based on this, the present disclosure proposes to adaptively adjust the signal value of the programming pulse applied to the page based on the P/E cycles of the page, so as to reduce the probability of over-programming of the page with the increase of the P/E cycles.

The present disclosure finds that the failed bit count of a page is related to the signal value of a programming pulse applied to the page, and after application of a programming pulse having the same signal value to different pages in an erased state, the failed bit counts of pages with different P/E cycles are different. In some embodiments, as the P/E cycles of the page increase, the failed bit count of the page gradually decreases.

Based on this, the present disclosure proposes to first apply the first programming pulse to the first page and obtain the failed bit count of the first page, and then adjust the first signal value based on the failed bit count of the first page to obtain the second signal value. Here, the second signal value enables the first page to be programmed into the programmed state without over-programming.

It can be understood that the second signal value is related to the failed bit count of the first page, and the failed bit count of the first page is related to the P/E cycles of the first page. Therefore, the second signal value is related to the P/E cycles of the first page. The programming method provided by the embodiment of the present disclosure adaptively adjusts the second signal value based on the P/E cycles of the first page, so that the second programming pulse applied to the first page can make the first page be programmed into the programmed state and the chance of over-programming may be reduced.

It can also be understood that when the NAND memory performs an erasing operation in units of blocks, the erasing times of each page in the same block are the same. Then, after applying the first programming pulse to the first page in the block, obtaining the failed bit count, and determining the second signal value, only one programming pulse (i.e., a third programming pulse) needs to be applied to the second page in the block (that is, other pages except the first page), so that the third signal value of the third programming pulse is equal to the second signal value and the second page can reach the programmed state by being applied with one programming pulse.

It can be seen from the above analysis that, compared to applying at least two programming pulses to each page in the block, the programming method provided by the embodiment of the present disclosure is applied to programming a single-level cell. As only the first page needs to be applied with more than one programming pulses, and the other pages (i.e., the second pages) in the block except the first page can be programmed into the programmed state by being applied with one programming pulse, the number of applying programming pulses can be reduced, thus shortening the programming time and increasing the write speed.

Further, according to the programming method provided by the embodiments of the present disclosure, the magnitude of the programming pulse signal value applied to the page is adaptively adjusted based on the P/E cycles of the page, so that the programming pulse signal value applied to the page enables the chance of over-programming to be reduced on the premise that the page is programmed into the programmed state, thereby achieving dynamic and fine-grained programming, reducing the threshold voltage shift of the programmed state of the memory cells in the page and the degradation of the erased state, improving the reliability of the memory and prolonging the lifetime of the memory. In brief, the programming method provided by the embodiments of the present disclosure enables the nonvolatile memory device to which the programming method provided by the present disclosure is applied to have the fine comprehensive performance of high read and write speed, long service life, and high reliability.

In some embodiments, the third signal value of the third programming pulse is equal to the sum of the first signal value and a first offset value.

The first offset value is the difference between a first target programming pulse signal value of the first page and the first signal value, a second target programming pulse signal value of the second page is equal to the first target programming pulse signal value, and the first offset value is obtained based on the failed bit count of the first page.

Here, the first target programming pulse signal value is the signal value of the corresponding programming pulse when the failed bit count of the first page is equal to the target failed bit count, namely, the signal value causing the first page being programmed into the programmed state and there being no over-programming.

The second target programming pulse signal value is the signal value of the corresponding programming pulse when the failed bit count of the second page is equal to the target failed bit count, namely, the signal value causing the second page being programmed into the programmed state and there being no over-programming. The second target programming pulse signal value may be equal to the first target programming pulse signal value, and may also be greater or smaller than the first target programming pulse signal value. As an example, the second target programming pulse signal values for a plurality of second pages may be equal and equal to the first target programming pulse signal values if the characteristic differences of the memory cells in the block are small from layer to layer. As another example, if the characteristic differences of the memory cells in the block are big from layer to layer, the target programming pulse signal values for the first page and the plurality of second pages in the block may not be exactly the same.

In this embodiment, the second target programming pulse signal value is equal to the first programming pulse signal value. The two described herein are equal, and the measurement error between them is allowable.

In this embodiment, a method for adjusting the first signal value based on the failed bit count of the first page is provided. In some embodiments, the first signal value is set to be smaller than the first target programming pulse signal value, and the first offset value is determined based on the failed bit count of the first page. A third signal value is obtained from the sum of the first signal value and the first offset value.

It can be understood that the first programming pulse using the first signal value does not cause the first page to be programmed into the programmed state, and the sum of the first signal value and the first offset value is equal to the first target programming pulse signal value. Therefore, the programming pulse employing the sum of the first signal value and the first offset value enables the first page to be programmed into the programmed state. Since the second target programming pulse signal value of the second page is equal to the first target programming pulse signal value, the third programming pulse can cause the second page to be programmed into the programmed state when the third signal value is equal to the sum of the first signal value and the first offset value. Based on this, in this embodiment, only the third programming pulse may be used to program the second page without repeating the programming steps of the first page on the second page, resulting in prolonged programming time.

In some embodiments, when the second target programming pulse signal value is less than the first target programming pulse signal value, the third programming pulse can also cause the second page to be programmed into the programmed state if the third signal value is equal to the sum of the first signal value and the first offset value, but there may be some degree of over-programming. In some embodiments, the second target programming pulse signal value is greater than the first target programming pulse signal value. If the third signal value is equal to the sum of the first signal value and the first offset value, then the third programming pulse may fail to cause the second page to be programmed into the programmed state. Therefore, the positional relationship of other pages relative to the first page is further required to be considered in determining the third signal value of the third programming pulse applied to the second page, so that the second page is programmed into the programmed state without over-programming.

In some embodiments, the third signal value of the third programming pulse is determined based on the first signal value, the failed bit count, and the positional relationship of the second page relative to the first page.

As an example, the third signal value of the third programming pulse is equal to the sum of the first signal value, the first offset value, and the second offset value; where the first offset value is obtained based on the failed bit count, and the second offset value is obtained based on the positional relationship of the second page relative to the first page.

In the embodiment of the present disclosure, the first offset value is related to the failed bit count, and the failed bit count of the first page under the first programming pulse is related to the P/E cycles of the block, that is, the first offset value is related to the P/E cycles of the block, and the second offset value is related to the position of the second page in the block. That is to say, the programming method provided by the embodiment of the present disclosure adaptively adjusts the magnitude of the programming pulse signal value applied to the page based on the P/E cycles of the page and the position of the page in the block, so that the programming pulse applied to the page enables the probability of over-programming to be reduced while the page is programmed into the programmed state, achieving dynamic and refined programming.

In some embodiments, the first offset value is obtained based on the failed bit count of the first page and the first correspondence. The first correspondence includes multiple fitting functions of the programming pulse signal values and the failed bit count, the multiple fitting functions are different, and the multiple fitting functions correspond to pages with different P/E cycles. Alternatively, the first correspondence includes a fitting function of the programming pulse signal values and the failed bit count, and the fitting function is applicable to pages with different P/E cycles.

In some embodiments, the second offset value is obtained based on the position of the second page and the second correspondence.

The second correspondence is used to indicate the relationship between the second offset value and the position of the second page.

Here, the steps of determining the first offset value based on the first correspondence and determining the second offset value based on the second correspondence may be performed by the memory controller. Therefore, the present disclosure will be described in detail in the programming method of the memory system later.

In some embodiments, before step S110, the programming method further includes obtaining a first signal value of the first programming pulse applied to the first page.

In some embodiments, before step S120, the programming method further includes obtaining a third signal value of the third programming pulse applied to the second page.

In some embodiments, after step S120, the programming method further includes performing programming verification on the second page.

As an example, performing programming verification on the second page includes applying a program verification pulse to the second page to obtain the failed bit count of the second page; and comparing the failed bit count of the second page with the target failed bit count.

When the failed bit count of the second page is less than or equal to the target failed bit count, the verification is passed.

In the embodiment of the present disclosure, the failure of programming the second page can be found in time by performing programming verification on the second page to confirm the programming result of the second page, so that corresponding remedial measures can be taken.

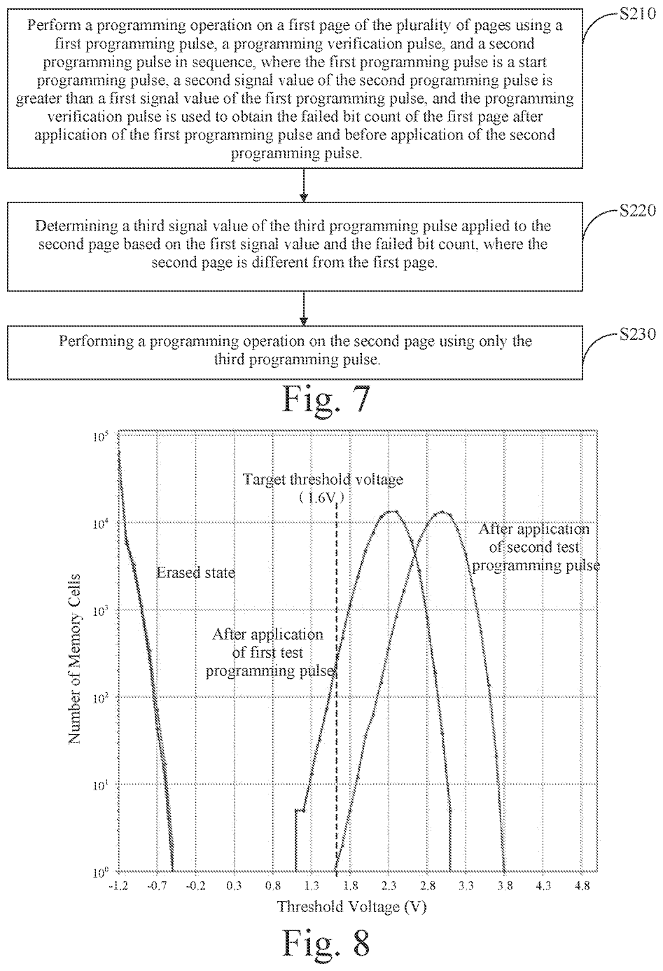

The present disclosure further provides a programming method for a memory system including a memory controller and a nonvolatile memory device. The non-volatile memory device is described above, the memory controller is configured to control the non-volatile memory device. The programming method for the memory system is illustrated in FIG. 7 and includes the following steps:
S210: perform a programming operation on a first page using a first programming pulse, a programming verification pulse, and a second programming pulse in sequence, where the first programming pulse is a start programming pulse, a second signal value of the second programming pulse is greater than a first signal value of the first programming pulse, and the programming verification pulse is used to obtain the failed bit count of the first page after application of the first programming pulse and before application of the second programming pulse;
S220: determining a third signal value of the third programming pulse applied to the second page based on the first signal value and the failed bit count, where the second page is different from the first page; and
S230: performing a programming operation on the second page using only the third programming pulse.

Here, step S210 may be controlled and executed by the memory controller. For example, the memory controller issues a first write command, which may include the first signal value, the signal value of the program verification pulse, and the second signal value. After receiving the first write command, the non-volatile memory device generates a first programming pulse, a programming verification pulse, and a second programming pulse, performs a programming operation on the first page, and counts the failed bit count of the first page after applying the programming verification pulse. In some embodiments, the signal value of the programming verification pulse may be stored in the peripheral circuit and invoked directly by the peripheral circuit rather than being sent from the memory controller.

In some embodiments, step S210 may be performed jointly by the memory controller and the non-volatile memory device. For example, the memory controller issues a first write command, which may include a first signal value, a signal value of a programming verification pulse, and a second signal value; after receiving the first write command, the peripheral circuit generates a first programming pulse, a programming verification pulse, and a second programming pulse, performs the programming operation on the first page, and counts the failed bit count of the first page after applying the programming verification pulse.

In some embodiments, step S210 may be performed by the non-volatile memory device. For example, the peripheral circuit stores a first signal value, a signal value of a program verification pulse, and a second signal value. The peripheral circuit directly generates a first programming pulse, a programming verification pulse, and a second programming pulse to perform the programming operation on the first page.

Step S220 may be performed by the memory controller. After obtaining the failed bit count of the first page, the memory controller determines the third signal value based on the first signal value and the failed bit count.

Step S230 may be performed by the memory controller. For example, the memory controller issues a second write command, which may include the third signal value.

In some embodiments, this step may also be performed jointly by the memory controller and the non-volatile memory device. For example, the memory controller issues a second write command including a third signal value; after receiving the second write command, the peripheral circuit generates a third programming pulse to program the second page.

In some embodiments, in step 210, the second signal value may be an empirical value, a signal value that is large enough to allow the first page to be programmed into the programmed state, rather than being determined based on the first signal value and the failed bit count.

In some embodiments, step S210 includes performing a programming operation on the first page using a first programming pulse and a programming verifying pulse in sequence; determining a second signal value based on the first signal value and the failed bit count; and performing a programming operation on the first page using the second programming pulse.

In some embodiments, before step S210, the programming method further includes determining the first signal value applied to the first page.

In some embodiments, the step of determining the first signal value applied to the first page may include the steps of: applying a first programming test pulse to the first page and performing program verification to obtain a first test failed bit count, when the first test failed bit count is greater than a target failed bit count; applying a second programming test pulse to the first page and performing program verification to obtain a second test failed bit count, where the signal value of the second programming test pulse is greater than that of the first programming test pulse; when the second test failed bit count is less than or equal to the target failed bit count, determining that the signal value of the first programming test pulse is the signal value of the first programming pulse.

Here, performing the program verification on the first page means applying a program verification pulse to the first page.

In some embodiments, the signal value of the second programming test pulse is equal to the sum of the signal value of the first programming test pulse and a preset increment value.

In some embodiments, the preset increment value is a fixed value.

In some embodiments, the preset increment value ranges from 300 mV to 600 mV, for example, 300 mV, 400 mV, 450 mV, 500 mV, 600 mV, etc. In FIG. 5, the median of programmed state threshold voltage margin of pages with 100k P/E cycles is 410 mV higher than the median of programmed state threshold voltage margin of unerased pages. The programming efficiency of the pages with 100k P/E cycles is about 80% of the programming efficiency of programming in the programmed state of the unerased pages. Therefore, the preset increment value can be set to 500 mV, so that the first signal value of the first programming pulse can be adapted to the programming of different pages with large differences in P/E cycles.

It should be noted that, after obtaining the first test failed bit count, if the first test failed bit count is less than or equal to the target failed bit count, it means that the signal value of the first programming test pulse has caused the first page to be programmed into the programmed state. The signal value of the first programming test pulse is too large. Therefore, it is necessary to re-apply the first programming test pulse with a smaller signal value from the erased state and perform verification.

In some embodiments, when the first test failed bit count is less than or equal to the target failed bit count, the first page is erased, and a third programming test pulse is applied to the erased first page, where the signal value of the third programming test pulse is less than the signal value of the first programming test pulse.

Here, the third programming test pulse is the first programming test pulse with a smaller signal value applied to the first page in the erased state.

The steps of erasing the first page and applying a first programming test pulse with a smaller signal value to the erased first page are repeated until the first test failed bit count is greater than the target failed bit count, then continuing to apply the second test programming pulse with a larger signal value to the test page.

After obtaining the second test failed bit count, if the second test failed bit count is greater than the target failed bit count, it means that the first page has not been programmed into the programmed state, then the first page is erased and is applied with a first programming test pulse with larger signal value and perform verification.

In some embodiments, when the second test failed bit count is greater than the target failed bit count, the first page is erased, and a fourth programming test pulse is applied to the erased first page, where the signal value of the fourth programming test pulse is greater than the signal value of the first programming test pulse.

Here, the fourth programming test pulse is the first programming test pulse with a larger signal value applied to the first page in the erased state.

Here, after applying a first programming test pulse with a larger signal value to the first page in the erased state, a second programming test pulse needs to be added and verification is required, and the first signal value may be determined after the first test failed bit count is greater than the target failed bit count, and the second test failed bit count is less than or equal to the target failed bit count.

In the step of determining the first signal value of the first programming pulse provided by the embodiment of the present disclosure, the maximum number of programming test pulses can be set to 2, and the preset increment value (referring to the difference between the signal value of the second programming test pulse and the signal values of the first programming test pulse) is a fixed value. By adjusting the signal value of the first programming test pulse, the first page is not programming into the programmed state after the first programming test pulse is applied and before the second programming test pulse is applied, while the first page is programmed into the programmed state after the application of the second programming test pulse, thereby obtaining the first signal value of the first programming pulse of the first page.

In some embodiments, when adjusting the signal value of the first programming test pulse, the signal value of the first programming test pulse can be increased or decreased by the preset increment value to obtain the signal values of the third programming test pulse and the fourth programming test pulse.

It can be understood that, in some embodiments, the range of the signal value of the first programming test pulse can be empirically limited, so that the signal value of the first programming test pulse is as close as possible to the finally determined first signal value, so as to shorten the time for determination of the first signal value, thereby saving programming time.

In some embodiments, the step of determining the first signal value of the first programming pulse may be performed by the non-volatile memory device. The non-volatile memory device implements programming by using ISPP mode, and sets the maximum number of programming pulses to 2. The first signal value is determined by the non-volatile memory device when the first page is programmed into the programmed state and the number of programming pulses is 2.

In some embodiments, the step of determining the first signal value of the first programming pulse can be accomplished by a memory controller that issues a third write command. The third write command includes: applying a first programming test pulse to the first page. The memory controller obtains the first test failed bit count and compares the first test failed bit count with the target failed bit count. When the first test failed bit count is greater than the target failed bit count, the memory controller sends a fourth write command. The fourth write command includes: applying a second programming test pulse to the first page, where the signal value of the second programming test pulse is greater than the signal value of the first programming test pulse. The memory controller obtains the second test failed bit count, and compares the second test failed bit count with the target failed bit count. When the second test failed bit count is less than or equal to the target failed bit count, the signal value of the first programming test pulse is determined to be the first signal value.

In some embodiments, the step of determining the first signal value of the first programming pulse may be performed jointly by the memory controller and the non-volatile memory device. For example, the memory controller issues a third write command including the signal value of the first programming test pulse. After receiving the third write command, the peripheral circuit generates a first programming test pulse and a programming verification pulse to program the first page, and counts the first test failed bit count. The memory controller obtains the first test failed bit count and compares it with the target failed bit count. When the first test failed bit count is greater than the target failed bit count, the memory controller sends the fourth write command including the signal value of the second programming test pulse. After receiving the fourth write command, the peripheral circuit generates a second programming test pulse and a programming verification pulse to program the first page, and counts the second test failed bit count. The memory controller obtains the second test failed bit count and compares it with the target failed bit count. When the second test failed bit count is less than or equal to the target failed bit count, the memory controller determines the signal value of the first programming test pulse is the first signal value.

FIG. 8 illustrates a threshold voltage profile of memory cells in the first page after applying the first programming test pulse and the second programming test pulse to the first page. The horizontal axis represents the threshold voltage, and the vertical axis represents the number of memory cells in the page. It can be seen from FIG. 8 that for the first programming test pulse that meets the requirements, after the first programming test pulse is applied, the threshold voltages of some of the memory cells are lower than the target threshold voltage (Vpv), that is, the first page is not programmed into the programmed state. After the second programming test pulse is applied, the threshold voltages of most of the memory cells are greater than the target threshold voltage, that is, the first page is programmed into the programmed state.

In some embodiments, the first signal value applied to the first page may be determined before step S210 is performed each time on the first page in the block. And, before step S210 is performed, an erasing operation is performed on the first page.

In some embodiments, one first signal value applicable to all blocks in the die may be determined for one die. In some embodiments, the step of determining the first signal value applied to the first page may include the steps of: obtaining first test signal values of a plurality of first test pages; wherein, the P/E cycles of the plurality of first test pages are different, and each first test signal value is the signal value of the first programming test pulse obtained when the first test failed bit count is greater than the target failed bit count (after applying the first programming test pulse to the first test page), and the second test failed bit count is less than or equal to the target failed bit count (after applying the second programming test pulse to the first test page); and determining first signal value applied to the first page based on the plurality of first test signal values.

Here, the die may include a plurality of blocks. Several blocks in specific positions in a die are selected as test blocks, and the P/E cycles of these test blocks are different, and each test block may include at least one first test page. For example, the P/E cycles of the test blocks may not be exactly the same, that is, there may be multiple test blocks corresponding to each P/E cycle.

Here, the steps of obtaining first test signal values of the plurality of first test pages and determining the first signal values based on the plurality of first test signal values may be performed by the memory controller.

Here, before the step of obtaining the first test signal values of the plurality of first test pages, the programming method further includes: determining the first test signal values of the plurality of first test pages.

The step of determining the first test signal value of the first test page is the same as the above-mentioned step of determining the first signal value of the first page. In some embodiments, a first programming test pulse is applied to the first test page and programming verification is made to obtain the first test failed bit count; when the first test failed bit count is greater than the target failed bit count, a second programming test pulse is applied to the first test page and programming verification is made to obtain the second test failed bit count; when the second test failed bit count is less than or equal to the target failed bit count, the signal value of the first programming test pulse is determined to be the first test signal value of the first test page.

In some embodiments, the determining a first signal value applied to the first page based on the plurality of first test signal values includes determining a minimum value among the plurality of first test signal values of the plurality of first test pages as the first signal value of the first programming pulse applied to the first page.

In some embodiments, the determining a first signal value applied to the first page based on the plurality of first test signal values includes: determining an average value of the plurality of first test signal values of the plurality of first test pages as the first signal value of the first programming pulse applied to the first page.

In some embodiments, the above steps may be performed prior to programming the die to determine the first signal value suitable for the first page of all blocks in a die.

It should be noted that, in some embodiments, the step of determining the first signal value suitable for the first page of all blocks in a die may also be completed in the fabrication stage of the non-volatile memory device.

In some embodiments, the step of determining the first signal value suitable for the first page of all blocks in a die may be performed either by a non-volatile memory device and a test machine at a fabrication stage, or by a non-volatile memory device, the memory controller and test machine.

For example, the test machine and the peripheral circuit jointly perform the step of determining the first test signal values of the plurality of first test pages. In some embodiments, the test machine issues a third write command including the signal value of the first programming test pulse; after receiving the third write command, the peripheral circuit generates a first programming test pulse and a programming verification pulse to program the first test page, and count the first test failed bit count; the test machine obtains the first test failed bit count and compares it with the target failed bit count; when the first test failed bit count is greater than the target failed bit count, the test machine sends a fourth write command including the signal value of the second programming test pulses; after receiving the fourth write command, the peripheral circuit generates a second programming test pulse and a programming verification pulse to program the first page, and counts the second test failed bit count; the test machine obtains the second test failed bit count, and compares it with the target failed bit count; and when the second test failed bit count is less than or equal to the target failed bit count, it is determined that the signal value of the first programming test pulse is the first test signal value.

In some embodiments, the test machine may also send a write command to the peripheral circuit via the memory controller, and obtain a plurality of first test signal values via the memory controller.

The test machine determines the first signal value based on the plurality of first test signal values.

After the first signal value suitable for the first page of all blocks in a die is determined, the first signal value is stored in the non-volatile memory device or the memory controller.

The non-volatile memory device usually includes a plurality of dies, and each die is varied in process. Therefore, in some embodiments, at least one first signal value is stored in the non-volatile memory device or the memory controller, and each first signal value corresponds to one die. Here, some of the first signal values among the plurality of first signal values may be equal.

Correspondingly, in the above programming method, before step S110 or step S210, the programming method may further include obtaining the stored first signal value of the first programming pulse based on the address of the first page. In this way, the programming time can be further shortened.

Here, the first signal value can be obtained based on page address of the first page, the first signal value can also be obtained based on the block address of the block where the first page is located, or the first signal value can be obtained based on the address of the die where the first page is located.

In some embodiments, a basic first signal value may also be stored in the non-volatile memory device. In the programming stage of the non-volatile memory device, the basic first signal value can be adjusted based on the position of the die to obtain the first signal value suitable for different dies during the programming of the die.

Here, the basic first signal value may be the first signal value corresponding to the specified die.

The present disclosure provides four ways of determining the first signal value. As mentioned above, the first way is to directly determine the first signal value on the first page before step S210 is executed. The first signal value determined in this way is more suitable, and it is unnecessary to set a test page for determining the first test signal value, which is beneficial to the improvement of memory integration.

The second way is to determine the first signal value suitable for the first page of all blocks in a die before a die is programmed each time. This method can improve programming efficiency.

The third way is to determine, for each die, the first signal value suitable to the first page of all blocks in the die during the fabrication stage of non-volatile memory device, and store it in the non-volatile memory device or in the memory controller. These first signal values can then be used directly when programming the non-volatile memory device. Although this way increases the manufacturing cycle of the non-volatile memory device, it can greatly improve the programming efficiency.

The fourth way is to store a basic first signal value in the non-volatile memory device during the fabrication stage of the non-volatile memory device, and store the basic first signal value in the non-volatile memory device or the memory controller. During the programming phase of the non-volatile memory device, the basic first signal value is adaptively adjusted based on the position of the die when programming of the die. In this way, both the fabrication cycle and programming efficiency of the non-volatile memory device can be attended to.

In some embodiments, step S220 includes: determining the first offset value based on the failed bit count, where the first offset value is the difference between the first target programming pulse signal value of the first page and the first signal value, and the second target programming pulse signal value of the second page is equal to the first target programming pulse signal value; and determining the sum of the first signal value and the first offset value as the third signal value.

In some embodiments, a first correspondence is stored in the memory controller or the non-volatile memory device. The first correspondence includes a fitting function of a plurality of programming pulse signal values and the failed bit count, the plurality of fitting functions are different, and multiple fitting functions correspond to pages with different P/E cycles. In some embodiments, the first correspondence includes a fitting function of a programming pulse signal value and the failed bit count, and the fitting function is suitable for pages with different P/E cycles.

Here, the first correspondence is obtained by applying programming pulses with different signal values to pages with different P/E cycles and applying a programming verification pulse after each application of the programming pulse to obtain the failed bit count.

In some embodiments, the non-volatile memory device may include a plurality of second test pages, and the P/E cycles of the plurality of second test pages are different. Determining the first correspondence may include the following steps: applying a plurality of programming test pulses to each second test page in turn, and after each application of the programming test pulse, performing program verification on the second test page to obtain the test failed bit count of the plurality of second test pages, where the signal values of multiple programming test pulses change in a stepwise manner; and determining multiple fitting functions based on programming pulse signal values of pages with different P/E cycles and the failed bit count according to the signal values of a plurality of programming test pulses applied to a plurality of second test pages and the corresponding test failed bit count obtained after applying each programming test pulse, where the first correspondence includes the plurality of fitting functions.

Here, performing programming verification on the second test page may be applying a programming verification pulse to the second test page.

In some embodiments, the P/E cycles of the plurality of second test pages may not be exactly the same. That is, there may be multiple test pages corresponding to each P/E cycle.

In some embodiments, the non-volatile memory device may include a plurality of test blocks, the P/E cycles of each test block are not exactly the same, and each test block may include a second test page. The position of the second test page in the test block is the same as the position of the first page in the block. For example, if the first page is WL0, the second test page is also WL0.

In some embodiments, the step of determining the first correspondence may be performed jointly by the non-volatile memory device and the memory controller.

For example, the memory controller sends a plurality of fifth write commands to the peripheral circuit in sequence, and each fifth write command includes the address of the second test page and the signal values of the plurality of programming test pulses applied to the second test page. After receiving the fifth write command each time, the peripheral circuit applies multiple programming test pulses to the second test page by means of ISPP to obtain multiple test failed bit counts. The memory controller obtains multiple test failed bit counts corresponding to each second test page from the peripheral circuit, and determines the first correspondence based on the signal value of the programming test pulse stored therein.

In some embodiments, the process of determining the first correspondence using a plurality of second test pages may determine the first correspondence before programming the first page of the first block of the non-volatile memory device for the first time.

In some embodiments, the process of obtaining the first correspondence using a plurality of second test pages may also be completed after the non-volatile memory device is fabricated and before the memory system is packaged and shipped from the factory, and the determined first correspondence may be stored in the memory controller or the non-volatile memory device. In this way, when the above-mentioned programming process is performed, the stored first correspondence can be directly obtained.

In some embodiments, the step of determining the first correspondence may be performed jointly by the non-volatile memory device and the test machine at the fabrication stage.

For example, the test machine sends a plurality of fifth write commands to the peripheral circuit in sequence, and each fifth write command includes the address of the second test page and the signal values of the plurality of programming test pulses applied to the second test page. After receiving the fifth write command each time, the peripheral circuit generates multiple programming test pulses and programming verification pulses to program the second test page, and counts multiple test failed bit counts. The test machine obtains a plurality of test failed bit counts corresponding to each second test page from the non-volatile memory device, and determines a first correspondence based on the signal values of the plurality of programming test pulses stored therein.

In some embodiments, the step of determining the first correspondence may be performed jointly by the non-volatile memory device, the memory controller, and the test machine. For example, the test machine sends the fifth write command to the peripheral circuit via the memory controller, and obtains the test failed bit count via the memory controller.

In addition, it should be noted that, in some embodiments, the first correspondence is obtained by conducting tests on a large number of dies and a large number of test blocks during the fabrication stage of the non-volatile memory device or the memory system. Therefore, the first correspondence provided by the embodiments of the present disclosure is basically suitable for all dies with the same or similar structure.

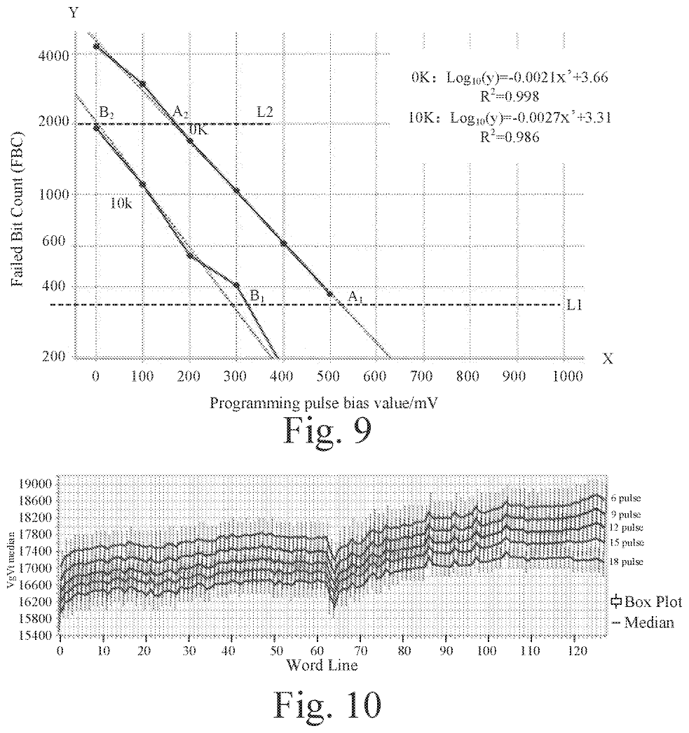

FIG. 9 illustrates a schematic diagram of a first correspondence according to an embodiment of the present disclosure. The point values connected to form a solid line in FIG. 9 are obtained through the above steps. The horizontal axis (x-axis) of FIG. 9 represents the programming pulse bias value, and the vertical axis (y-axis) represents the failed bit count (FBC) of the page.

Here, the programming pulse bias value is the difference between the programming pulse signal value and the preset programming pulse signal value, and is only set to simplify the fitting function. The preset programming pulse signal value can be any value, and does not affect the size of the first offset value.

For example, the preset programming pulse signal value may be 17V. Then, in FIG. 9, the programming pulse bias value of the horizontal axis is 0 mV, and the corresponding programming pulse signal value is 17V. As an analogy, the programming pulse bias values of the horizontal axis are 100 mV, 200 mV, 300 mV, 400 mV, 500 mV, 600 mV, 700 mV, 800 mV, 900 mV, and 1000 mV, corresponding to programming pulse signal values of 17.1V, 17.2V, 17.3 V, 17.4V, 17.5V, 17.6V, 17.7V, 17.8V, 17.9V, 18V respectively.

FIG. 9 shows a fitting straight line based on the programming pulse bias value and the logarithm of the failed bit count for an unerased page (the P/E cycles are the initial P/E cycles, for example, 0), and a fitting straight line based on programming pulse bias value and the logarithm of the failed bit count for a page with 10k P/E cycles.

Here, it should be noted that the relationship between the failed bit count and the programming pulse bias value does not satisfy the linear relationship, but the relationship between log base 10 of the failed bit count (log₁₀(FBC)) and the programming pulse bias value satisfies the linear relationship. Therefore, the vertical axis in FIG. 9 is set unequally. In other words, if you want the vertical axis of FIG. 9 to be equally divided, then the vertical axis of FIG. 9 can be modified to log base 10 of the failed bit count of the page (log₁₀(FBC)).

Take the fitting straight line corresponding to the unerased page as an example, the value of each point on the fitting straight line is the failed bit count obtained after performing programming and programming verification on the unerased page under the condition of a certain preset programming pulse signal value. In some embodiments, the preset programming pulse signal value may include 17V, the point value corresponding to the programming pulse bias value of 0 refers to programming under the condition of 17V, and the failed bit count is about 4000; the point value corresponding to programming pulse bias value of 300 milliseconds (mV) refers to programming under the condition of 17.3V, and the failed bit count is about 1000; the point value corresponding to the programming pulse bias value of 400 mV refers to programming under the condition of 17.4V, and the failed bit count is about 600.

FIG. 9 illustrates the failed bit count obtained by taking the preset programming pulse signal value as the starting signal value, adding different programming pulse bias values to the preset programming pulse signal value to obtain the programming pulse signal value, applying the programming pulse signal value to the page and performing verification.

In FIG. 9, by fitting a plurality of point values obtained by programming an unerased page with different programming pulse signal values, a fitting straight line between the programming pulse bias value and the failed bit count for the unerased page is obtained. The fitting function corresponding to the fitted straight line is log₁₀(y)=3.66−0.0021x′, R²=0.998, where x′ is the programming pulse bias value, y is the failed bit count, and R² is the coefficient of determination of linear regression, which reflects the goodness of fit of the model. The closer R² is to 1, the better the fitting equation and the more accurate the model. In some embodiments, the least squares approach may be used to fit multiple point values to obtain a fitted straight line and a fitting function corresponding to an unerased page.

In the same way as obtaining the fitting straight line corresponding to the unerased page, the fitting straight line between the programming pulse bias value and the failed bit count for the page with 10k P/E cycles can be obtained, and the fitting function corresponding to the fitting straight line is log₁₀(y)=3.31−0.0027x′, R²=0.986.

Similarly, multiple fitting functions of the programming pulse bias value and the failed bit count for pages with different P/E cycles can be obtained. The first relationship includes the plurality of fit functions.

Referring to FIG. 9, a method for determining the first offset value based on the first correspondence and the failed bit count will be described below, and the reliability of the method is analyzed.

The ordinate of the dotted line L1 extending parallel to the horizontal axis in FIG. 9 represents the corresponding failed bit count when the page is programmed into the programmed state, that is, the target failed bit count. In this embodiment, the target failed bit count is 300. The abscissa corresponding to the intersection of the dotted line L1 and the fitted straight line is the corresponding programming pulse bias value causing the page to be programmed into the programmed state. For example, the abscissa corresponding to the intersection point A₁ of the dotted line L1 and the fitting straight line of the unerased page indicates that the corresponding programming pulse bias value causing the unerased page to be programmed into the programmed state is 550 mV, and the programming pulse signal value is 17.55V.

In some embodiments, as shown in FIG. 9, the first correspondence includes a fitting function based on the failed bit count and a programming pulse signal value for a plurality of pages with different P/E cycles, and the plurality of fitting functions include a first fitting function. The first fitting function is a fitting function corresponding to the P/E cycles of the first page.

Here, the fitting function based on the failed bit count and the programming pulse signal value for multiple pages with different P/E cycles may include: log₁₀(y)=a₁+b₁x, log₁₀(y)=a₂+b₂x, . . . log₁₀(y)=aᵢ+bᵢx, . . . log₁₀(y)=aₙ+bₙx, where i and n are integers, n is less than or equal to the P/E cycles of the first page, x is the programming pulse signal value, y is the failed bit count, aᵢ and bᵢ are constants, aᵢ and bᵢ in multiple fitting functions are not exactly the same.

It can be understood that the programming pulse bias value x′ is equal to the difference between the programming pulse signal value x and the preset programming pulse signal value c. That is, x′=x−c. When the fitting function of the programming pulse offset bias value and the failed bit count for the unerased page is log₁₀(y)=3.66−0.0021x′, the programming pulse signal value and the failed bit count for the unerased page satisfy log₁₀(y)=3.66−0.0021(x−c)=(3.66+0.0021c)−0.0021x.

In step S120, the step of determining the first offset value based on the failed bit count includes: obtaining a first correspondence, where the first correspondence includes a fitting function based on the failed bit count and a programming pulse signal value for a plurality of pages with different P/E cycles, and the plurality of fitting functions include a first fitting function, and the first fitting function is a fitting function corresponding to the P/E cycles of the first page; determining the first fitting function among the plurality of fitting functions based on the first signal value and the failed bit count; substituting the target failed bit count into the first fitting function to determine the first target programming pulse signal value; and determining the first offset value based on the difference between the first target programming pulse signal value and the first signal value.

Here, the step of determining the first offset value based on the failed bit count is performed by the memory controller, and the obtaining the first correspondence may be that the memory controller invokes the first correspondence of its own memory, or the memory controller invokes the first correspondence stored in the non-volatile memory device.

The step of selecting the first fitting function may be: substituting the first signal value of the first page into the plurality of fitting functions in the first correspondence, thereby calculating the failed bit count corresponding to different fitting functions, and selecting therefrom the corresponding fitting function whose failed bit count is closest to that of the first page, as the first fitting function for determining the first offset value of the first page.

The analysis in conjunction with FIG. 9 and the specific embodiment is as follows. For example, when the signal value of the first programming pulse is 17V (the programming pulse bias value is 0 mV), and the failed bit count obtained is 4000, the value of this point is closest to the fitting straight line of the unerased page in the direction of the vertical axis, thereby determining that the fitting straight line of the unerased page is the fitting straight line corresponding to the first fitting function. Next, as shown in FIG. 9, the abscissa of the intersection A₁ of the fitting straight line of the unerased page and the dotted line L1 is the target programming pulse signal value of 17.55V (corresponding to the programming pulse bias value of 550 mV), and it is determined from the difference between 17.55V and 17V that the first offset value is 550 mV.

Referring to FIG. 9 again, when the signal value of the first programming pulse is still 17V (the programming pulse bias value is 0 mV), and the failed bit count obtained is 2000, the value of this point is closest to the fitting straight line for the pages with 10K P/E cycles in the direction of the vertical axis, so it is determined that the fitting straight line for pages with 10K P/E cycles is the fitting straight line corresponding to the first fitting function. As shown in FIG. 9, the abscissa of the intersection point B₁ of the fitted straight line for pages with 10K P/E cycles and the dotted line L1 is the target programming pulse signal value of 17.3V (corresponding to the programming pulse bias value of 300 mV), and it is determined from the difference between 17.3V and 17V that the first offset value is 300 mV.

It can be seen from the above two specific embodiments that after applying the first programming pulse value of 17V to both the unerased page and the page with 10k P/E cycles, the corresponding first offset value can be determined to be 550 mV from failed bit count of the unerased page being 4000, and the corresponding first offset value can be determined to be 300 mV based on the failed bit count of a page with 10k P/E cycles being 2000. It can be seen that with the increase of the P/E cycles of the page, the first offset value gradually decreases, which is consistent with the rule that the programmed state threshold voltage margin of the page gradually increases with the increase of the P/E cycles as reflected in the above FIG. 5. It can be understood that, after applying programming pulses having the same signal value to pages with different P/E cycles in DSLC mode in FIG. 5, the programmed state threshold voltage margin of pages with more P/E cycles is larger, indicating the greater degree of over-programming. Therefore, a smaller first offset value is required when programming is performed using the programming method provided in the embodiment of the present application.

This also shows that the method for determining the first offset value provided by the embodiment of the present application is reliable. First, the first offset value can be adaptively adjusted based on the P/E cycles of the page; secondly, the method of determining the first offset value based on the first failed bit count can satisfy the rule that the first offset value gradually decreases as the P/E cycles of a page increase.

Further, it can be seen from FIG. 9 that the slopes of the fitted straight lines corresponding to pages with different P/E cycles are substantially the same.

Taking the first signal value of the first programming pulse as 17V and the failed bit count as 2000 as an example, it can be seen from the above embodiment that the fitting straight line of a page with 10k P/E cycles should be selected as the fitted straight line corresponding to the first fitting function for determining the first offset value, and the first offset value should be the difference between the abscissa value of point B₁ and the abscissa value of point B₂.

Here, a dotted line L2 parallel to the horizontal axis is drawn in FIG. 9, and the intercept of L2 on the vertical axis is 2000, that is, the dotted line L2 passes through point B₂, and the intersection of dotted line L2 and the fitting straight line of the unerased page is A₂. Since the slope of the fitted straight line of the page with 10k P/E cycles is the same as that of the fitting straight line of the unerased page, it can be easily concluded that the difference between the abscissa value of point A₁ and the abscissa value of point A₂ is equal to the difference between the abscissa value of point B₁ and the abscissa value of point B₂. This shows that the first offset value determined by the fitting straight line of the unerased page is equal to the first offset value determined by the page with 10k P/E cycles. Therefore, the fitting straight line of the unerased page can be used instead of the fitting straight line of a page with 10k P/E cycles to determine the corresponding first offset value obtained when the first signal value of the first page is 17V and the failed bit count is 2000.

As an analogy, it can be concluded that in the embodiment of the present disclosure, the first offset value of the page with different P/E cycles can be determined only using the fitted straight line corresponding to the unerased page. Therefore, in some embodiments, the first correspondence includes a fitting function of the programming pulse signal value and the failed bit count, and the fitting function is suitable for pages with different P/E cycles.

Here, the fitting function is log₁₀(y)=a+bx, where x is the programming pulse signal value, y is the failed bit count, and a and b are constants.

In step S120, the step of determining the first offset value based on the failed bit count includes: obtaining a first correspondence, where the first correspondence includes a fitting function of the programming pulse signal value and the failed bit count, and the fitting function is suitable for pages with different P/E cycles; substituting the target failed bit count into the fitting function to determine the first relative programming pulse signal value; substituting the failed bit count of the first page into the fitting function to determine the second relative programming pulse signal value; and determining the first offset value based on the difference between the first relative programming pulse signal value and the second relative programming pulse.

Here, it should be noted that the first correspondence may include a fitting function of programming pulse signal values and the failed bit count for a page with any P/E cycles.

In some embodiments, the first correspondence includes a fitting function of the programming pulse signal values and the failed bit count for the unerased page.

With reference to FIG. 9 and specific embodiments, the following descriptions are given as follows: as shown in FIG. 9, the intersection point A₁ of the dashed line L1 and the fitting straight line corresponding to the unerased page indicates that the target failed bit count is substituted into the fitting function corresponding to the unerased page, and it is determined that the first relative programming pulse signal value is 17.55V (the programming pulse offset value is 550 mV).

When the signal value of the first programming pulse is still 17V and the failed bit count obtained is 2000, the intersection point A₂ of the dotted line L2 and the fitted straight line corresponding to the unerased page indicates that the failed bit count of the first page is substituted into the fitting function corresponding to the unerased page, and it is determined that the second relative programming pulse signal value is 17.17V (the programming pulse offset value is 170 mV). The first offset value is determined to be 380 mV from the difference between 550 mV and 170 mV. There is a certain error compared with the 300 mV determined above, mainly due to the fact that the slopes of the unerased page and the page with 10k P/E cycles are −0.0021 and −0.2217 respectively, which are not completely consistent, but the error is within an acceptable range.

Here, verification is performed by using the fitting function of the programming pulse signal values and the failed bit count for the unerased page. From the fitting function log₁₀(y)=3.66-0.0021x′ of the programming pulse bias value and the failed bit count for the unerased page, it can be inferred that the fitting function of the programming pulse signal values and the failed bit count for the unerased page is: log₁₀(y)=3.66−0.0021(x−17)=(3.66+0.002*17)−0.0021x. The target failed bit count is set to y₁, the value of the first relative programming pulse signal to x₁, the failed bit count of the first page to y₂, and the value of the second relative programming pulse signal to x₂, obtaining log₁₀(y₁)=(3.66+0.0021*17)−0.0021x₁, log₁₀(y₂)=(3.66+0.0021*17)−0.0021x₂; the first offset value Δ is equal to the difference between the first relative programming pulse signal value and the second relative programming pulse signal value, that is, Δ=x₁−x₂=(log₁₀(y₁)−log₁₀(y₂))/−0.0021, substituting y₁=300, y₂=2000 to get the first offset value of 392 mV. This is consistent with the result 380V determined from the fitted straight line in FIG. 9.

In addition, it can be known from the calculation formula of the first offset value Δ=x₁−x₂=(log₁₀(y₁)−log₁₀(y₂))/b that the first offset value has nothing to do with the preset programming pulse signal value and the first signal value, and the first offset value is only related to the target failed bit count, the failed bit count of the first page, and the slope b of the first fitting function. The target failed bit count and the slope b of the first fitting function are known. Therefore, in the actual programming process, the first offset value can be calculated directly based on the failed bit count of the first page.

Compared with the embodiment in which the first correspondence includes multiple fitting functions, the present embodiment can omit the step of determining the first fitting function from the multiple fitting functions corresponding to pages with different P/E cycles, and determine the first offset value by only substituting the failed bit count of the first page into the formula Δ=(log₁₀(y₁)−log₁₀(y₂))/b, and the steps of determining the first offset value can be simplified to speed up programming.

It can be seen from the above embodiments of the present disclosure that when the logarithm value of the failed bit count of multiple pages with different P/E cycles and the slope of the fitting function of the programming pulse signal value are not the same, and the difference is large, the first corresponding should include a fitting function based on the programming pulse signal values and the failed bit count for multiple pages with different P/E cycles. In this way, the obtained first offset value can be more accurate.

When the slopes of the fitting functions of the logarithm value of the failed bit count and the programming pulse signal value for multiple pages with different P/E cycles are substantially the same, the first correspondence may be set to include only the fitting function of the failed bit count and the programmed pulse signal values for one page with any P/E cycles. In this way, the step of determining the first offset value can be simplified and the programming speed can be accelerated.

Here, the slope of the linear function of the logarithm value of the failed bit count and the programming pulse signal value for multiple pages with different P/E cycles being basically the same includes the case where the slopes are exactly identical, and also includes the case where multiple slopes are not exactly identical, but the difference is small and within the allowable error range.

In some embodiments, step S220 includes determining the third signal value applied to the second page based on the first signal value, the failed bit count, and the positional relationship of the second page with respect to the first page.

As an example, the step of determining the third signal value applied to the second page based on the first signal value, the failed bit count, and the positional relationship of the second page with respect to the first page includes: determining the first offset value based on the failed bit count; determining the second offset value based on the positional relationship of the second page relative to the first page; and determining the sum of the first signal value, the first offset value and the second offset value as the third signal value.

Here, the step of determining the first offset value based on the failed bit count is as described above, so it will not be repeated here.

In some embodiments, a second correspondence is stored in the memory controller, and the second correspondence is used to indicate the relationship between the second offset value and the position of the second page.

In some embodiments, the step of determining the second offset value based on the positional relationship of the second page relative to the first page includes: obtaining the second correspondence; and obtaining the position of the second page, and matching the second offset value corresponding to the second page in the second correspondence based on the position of the second page.

Here, the steps of obtaining the second correspondence and determining the second offset value based on the second correspondence and the position of the second page may be performed by the memory controller.

In some embodiments, before the step of obtaining the second correspondence, the step further includes: determining the second correspondence.

As an example, the non-volatile memory device may include at least one test block, each test block includes a plurality of third test pages, and the test blocks may be tested to determine the second correspondence. In some embodiments, determining the second correspondence includes the following steps: applying programming test pulses having the same signal value to each of the third test pages in the same test block; obtaining the gate signal value (V_{g}) and the threshold signal value (Vₜ) of each memory cell in the third test page; determining characteristic signal values of each third test page based on gate signal values and threshold signal values of the plurality of memory cells in each third test page; and obtaining the characteristic signal value of each third test page in the test block to determine the second correspondence.

Here, the step of determining the second correspondence may be performed jointly by the memory controller and the nonvolatile memory device. For example, the memory controller sends a sixth write command to the peripheral circuit, and the sixth write command includes the address of the test block and the signal value of the programming test pulse; after receiving the sixth write command, the peripheral circuit can apply the programming test pulses with the same signal value to each third test page in the test block; the memory controller obtains the gate signal value and threshold signal value of each memory cell in the third test page, determines the characteristic signal value, and thus determines the second correspondences.

As an example, the gate signal value includes a gate voltage, and the threshold signal value includes a threshold voltage. The gate voltage can be regarded as the voltage of the programming test pulse applied to the test page.

It can be understood that after applying the programming test pulse with the same signal value to each third test page, the gate signal value of each memory cell in the test page is substantially the same, and the threshold signal value is related to the characteristics of each memory cell. Therefore, the changing of the second offset value can be reflected with the characteristic signal value determined from the gate signal value and the threshold signal value.

As an example, determining the characteristic signal value of each third test page based on gate signal values and threshold signal values of the plurality of memory cells in each third test page includes: calculating a first difference between the gate signal value and the threshold signal value of each memory cell in each third test page; and determining the median of a plurality of first difference values corresponding to each memory cell in the third test page as the characteristic signal value of the test page.

In some embodiments, obtaining the characteristic signal values of each third test page in the test block to determine the second correspondence includes: obtaining the characteristic signal value of each third test page in the test block; and selecting a third test page at the same position as the first page from the plurality of third test pages, taking the difference between the characteristic signal values of other third test pages and the characteristic signal values of the selected third test page at the same position as the first page as a second offset value corresponding to the second page, and establishing a second correspondence between the second offset value and the position of the second page.

As an example, programming test pulses with the same signal value may be applied to each third test page in an ISPP programming manner.

In some embodiments, programming test pulses with the same signal value may be applied to each third test page in the same test block multiple times, and the signal values of the applied programming test pulses are different each time, so as to enrich the sample size and make the obtained second offset value accurate.

In some embodiments, there are multiple test blocks, and at least two test blocks in the multiple test blocks have different P/E cycles, so as to enrich the sample size and make the obtained second offset value accurate.

FIG. 10 illustrates a relationship diagram between the position of a page and the characteristic signal value of the page according to an embodiment of the present disclosure. Referring to FIG. 10, the horizontal axis of which represents the position of the page, and the vertical axis represents the characteristic signal value (V_{g}Vₜ median) of the page. In some embodiments, each block includes a plurality of stacked pages (i.e., word lines), and each page can be numbered from bottom to top or from top to bottom. The box plot at each point value on the solid line shown in FIG. 10 is the profile of the difference between the gate voltage and the threshold voltage of each memory cell in the page, and each point value is the median of the box plot (also is the characteristic signal value of the page).

It should be noted that, FIG. 10 is obtained by applying the programming test pulses with the same signal value to each page in the same block by using the ISPP programming method five times, and the applied signal value is different each time. Referring to FIG. 10, from top to bottom, the first curve is obtained by applying 6 programming pulses to each page in the same block, the second curve is obtained by applying 9 programming pulses to each page in the same block, and the remaining curves are obtained by applying 12, 15 and 18 programming pulses to each page in the same block respectively. The reason for this setting is that when the step voltage of ISPP is fixed, the memory cell will exhibit a stable programming efficiency as the programming voltage gradually increases. It is generally believed that the programming efficiency of the memory cell is stable with the application of 6 to 18 programming pulses. Thus, the measured V_{g}Vₜ can be guaranteed to be more accurate.

As shown in FIG. 10, after the programming test pulses with the same signal value are applied to each page in the same block, the characteristic signal values of the pages at different positions are different, which indicates that the programming pulses signal values that make the pages at different positions in the same block be programmed into the programmed state are different.

Based on the position of the page and the characteristic signal value of the page shown in FIG. 10, the difference between the characteristic signal values of the second test page and the first test page in the test block can be determined as the second offset value of the second page relative to the first page, and a second correspondence between the plurality of second offset values and the positions of the plurality of second pages is established. In the second correspondence established in this way, the offset value is adaptively set according to the page at each position, and the accuracy is high.

It should be noted here that the second offset value may be positive, negative, or zero, depending on the magnitudes of the first target programming pulse signal value of the first page and the second target programming pulse signal value of the second page. When the second target programming pulse signal value of the second page is greater than the first target programming pulse signal value of the first page, the second offset value is positive. When the first target programming pulse signal value of the first page is equal to the second target programming pulse signal value of the second page, the second offset value is zero. When the second target programming pulse signal value of the second page is smaller than the first target programming pulse signal value of the first page, the second offset value is negative.

Here, it can be understood that the second offset value is not necessary, and when the second offset value is zero or negative, the third signal value can still cause the second page to be programmed into the programmed state.

In some embodiments, the second offset values of every several adjacent second pages may also take the same value. For example, the second offset values of pages 0 to 10 have the same value, and the second offset values of pages 11 to 20 have the same value. In this way, the second correspondence can be simplified, so as to further improve the programming speed.

It should be noted that, in the above-mentioned embodiment, the second correspondence is determined in the multiple test blocks of the memory during the programming stage.

In some embodiments, the process of using the test block to determine the second correspondence may also be completed after the non-volatile memory device structure is fabricated and before the memory system is packaged and shipped from the factory, and the determined second correspondence may be stored in the memory controller or in a non-volatile memory device. In this way, when the above programming process is performed, the second correspondence in the memory controller can be directly invoked, or the memory controller can invoke the second correspondence from the non-volatile memory device. In this way, the programming process can be simplified, and programming time can be saved.

Here, the step of determining the second correspondence may be performed jointly by the nonvolatile memory device and the test machine. For example, the test machine sends a sixth write command to the peripheral circuit, and the sixth write command includes the address of the test block and the signal value of the programming test pulse; after receiving the sixth write command, the peripheral circuit applies programming test pulses with the same signal value to each third test page in the test blocks; the test machine obtains the gate signal value and threshold signal value of each memory cell in the third test page, determines the characteristic signal value, and thereby determines the second correspondence.

In some embodiments, the step of determining the second correspondence may be performed jointly by the non-volatile memory device, the memory controller, and the test machine. For example, the test machine sends the sixth write command to the peripheral circuit via the memory controller, obtains the gate signal value and the threshold signal value via the memory controller, then determines the characteristic signal value based on the gate signal value and the threshold signal value, and thereby determines the second correspondence.

The first offset value and the second offset value provided by the embodiment of the present disclosure are relatively accurate. Therefore, after the third programming pulse is applied to the second page, the probability of the second page being programmed into the programmed state is high. Therefore, it is unnecessary to perform programming verification on the second page to verify whether the second page has been programmed into the programmed state, which is beneficial to further shorten the programming time.

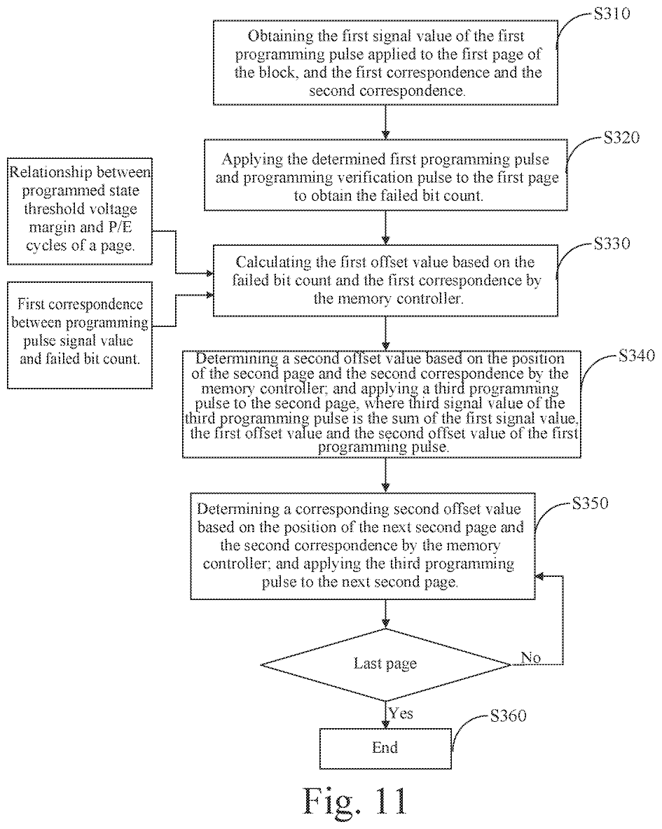

FIG. 11 illustrates a schematic flowchart of programming a block according to an embodiment of the present disclosure. Referring to FIG. 11, the programming method provided by this embodiment includes the following steps:
S310: obtaining the first signal value of the first programming pulse applied to the first page of the block, and the first correspondence and the second correspondence;
S320: applying the determined first programming pulse and programming verification pulse to the first page to obtain the failed bit count;
S330: calculating the first offset value based on the failed bit count and the first correspondence by the memory controller;
S340: determining a second offset value applied to the second page based on the position of the second page and the second correspondence by the memory controller; and applying a third programming pulse to the second page, where third signal value of the third programming pulse is the sum of the first signal value, the first offset value and the second offset value of the first programming pulse;
S350: determining a second offset value applied to a next second page based on the position of the next second page and the second correspondence by the memory controller; and applying the third programming pulse to the next second page; and
S360: programming each second page in sequence in light of the above process, until the programming of all pages in the block is completed, and then ending the programming of the block.

In some embodiments, step S310 is performed before starting to program the block.

In step S310, the memory controller stores the first correspondence, the second correspondence and the first signal value. In some embodiments, the first correspondence, the second correspondence, and the first signal value may also be stored in a peripheral circuit of the non-volatile memory device.

Step S320 may be performed by a non-volatile memory device.

In step S330, the memory controller may directly invoke the first correspondence stored therein, or may invoke the first correspondence stored in the peripheral circuit.

In step S340, the memory controller may directly call the first signal value and the second correspondence stored therein, or may call the first signal value and the second correspondence stored in the peripheral circuit. The memory controller determines the third signal value from the first signal value, the first offset value, and the second offset value corresponding to the first second page.

The non-volatile memory device generates a third programming pulse to program the second page, and the third programming pulse has a third signal value.

In step S350, the memory controller determines the third signal value applied to the next second page from the first signal value, the first offset value and the second offset value corresponding to the next second page. Application of a third programming pulse to the next second page is performed by the non-volatile memory device, and the third programming pulse has the third signal value.

In the programming method according to this embodiment, the first signal value, the first correspondence and the second correspondence of the first programming pulse are determined in advance (for example, in the fabrication stage of the memory), so that the programming time can be shortened to the greatest extent and programming efficiency is improved. Moreover, the first offset value is determined from the first correspondence, and the first offset value of the first page with different P/E cycles is different, so as to achieve dynamic and refined programming based on the P/E cycles of the page. The second offset value is determined from the position of the second page relative to the first page, so that the programming can be dynamically refined based on the position of the page in each block.

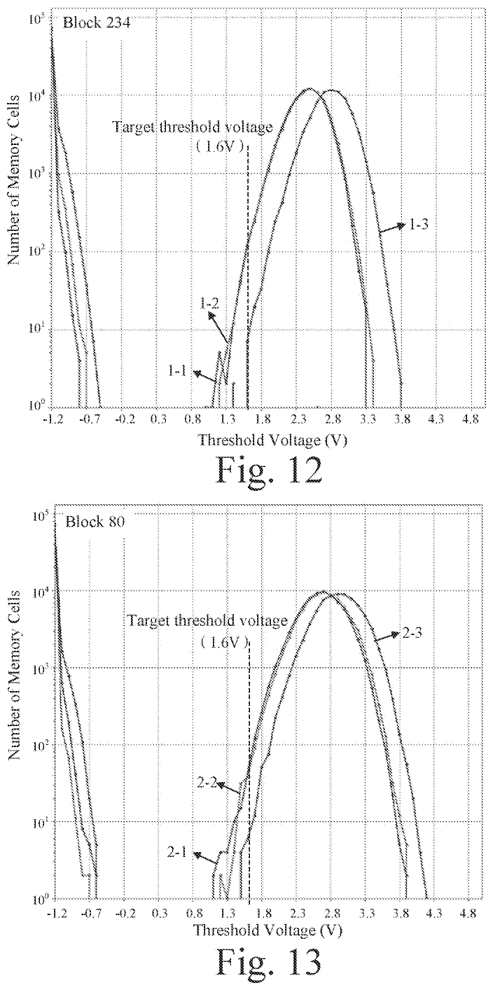

FIG. 12 and FIG. 13 list the threshold voltage profile of first page (WL0) and the second page (WL1) obtained by executing the programming method shown in FIG. 6 for two blocks with different P/E cycles (block 234, block 80 respectively). The P/E cycles of block 234 is 10k, and the P/E cycles of block 80 is 90k. Referring FIG. 12 and FIG. 13, the horizontal axis represents the threshold voltage, and the vertical axis represents the number of memory cells in the page. Curves 1-1 and 2-1 represent the threshold voltage distribution curves of the memory cells in the first page after applying the first programming pulse; curves 1-2 and 2-2 represent the threshold voltage distribution curves of the memory cells in the second page after applying the first programming pulse; curves 1-3 and 2-3 represent the threshold voltage distribution curves of the memory cells in the second page after applying a third programming pulse with a signal value equal to the sum of the first signal value, the first offset value and the second offset value.

In FIG. 12, it can be seen from curve 1-1 that after applying the first programming pulse to the first page of block 234, the first page is not programmed into the programmed state, and the failed bit count obtained is 2210.

As can be seen from curve 1-2, after the first programming pulse is applied to the second page of block 234, the second page is also not programmed into the programmed state.

This experiment determines that the sum of the first offset value and the second offset value is 500 mV based on the failed bit count being 2210 and the position of the second page. Next, a third programming pulse having a signal value equal to the sum of the first signal value, the first offset value and the second offset value is applied to the second page.

It can be seen from the curve 1-3 that when the signal value of the third programming pulse is the sum of the first signal value, the first offset value and the second offset value, the second page is programmed into the programmed state. This shows that the programming method provided by the embodiment of the present disclosure is feasible, and the magnitude of the signal value of the programming pulses can be precisely controlled.

In FIG. 13, it can be seen from the curve 2-1 that after the first programming pulse is applied to the first page of the block 80, the first page is not programmed into the programmed state, and the failed bit count obtained is 769.

As can be seen from curve 2-2, after the first programming pulse is applied to the second page of block 80, the second page is also not programmed into the programmed state.

In this experiment, the sum of the first offset value and the second offset value is determined to be 300 mV based on the first failed bit count of 769 and the position of the second page. Next, a third programming pulse having a signal value equal to the sum of the first signal value, the first offset value and the second offset value is applied to the second page.

It can be seen from curve 2-3 that when the signal value of the third programming pulse is the sum of the first signal value, the first offset value and the second offset value, the second page is programmed into the programmed state. This shows that the programming method provided by the embodiment of the present disclosure is feasible, and the magnitude of the signal value of the programming pulses can be precisely controlled.

It can also be seen from FIG. 12 and FIG. 13 that the first offset value is different for blocks with different P/E cycles, indicating that the present disclosure can adjust the first offset value based on the P/E cycles of the block, and finely control the signal value of the programming pulses while improving programming time and lifetime of the memory.

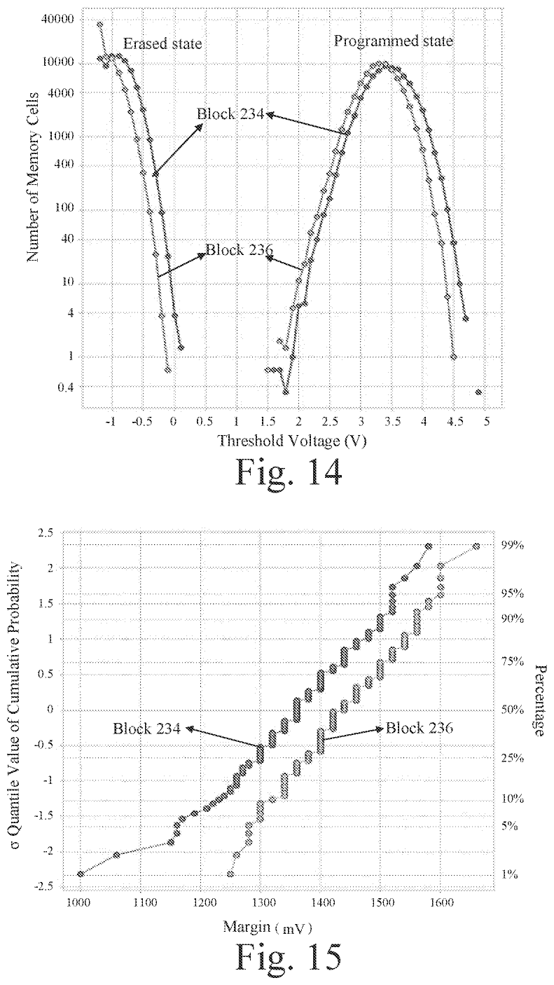

FIG. 14 illustrates the threshold voltage distribution curve of the memory cell in the page (word line 64) after 100 P/E cycles of the same page (word line 64) of two blocks (numbered block 234 and block 236) by employing the DSLC method and the programming method provided by the embodiments of the present disclosure. In FIG. 13, the horizontal axis represents the threshold voltage, and the vertical axis represents the number of memory cells. The DSLC method is employed for block 234. That is, programming pulses of 20.7V are applied throughout the 0 to 100k programming cycles. The programming method provided by the embodiments of the present disclosure is employed for block 236. That is, programming pulses of 20.7V are applied throughout the 0 to 50k programming cycles, and programming pulses of 20.4V are applied throughout the 50k to 100k programming cycles.

As shown in FIG. 14, the threshold voltage of the programmed state of word line 64 in block 236 is less shifted, the erased state is less degraded, the margin between the erased and programmed states is wider, and the memory has higher reliability.

FIG. 15 illustrate a Cumulative Distribution Function (CDF) of the margin between the erased state threshold voltage and a particular voltage of word line 64 in block 234 and block 236. Here, the specific voltage is the read voltage of the single-level cell. In FIG. 15, the horizontal axis represents the margin, the vertical axis represents the σ quantile value and the percentage of the cumulative probability, respectively, where the left vertical axis is the σ quantile value of the cumulative probability, and the right vertical axis is the percentage. As shown in FIG. 15, the probability that the margin between the erased state threshold voltage of word line 64 in block 236 and the specified voltage is less than or equal to 1300 mV is about 5% to 10%, while the probability that the margin between the erased state threshold voltage of word line 64 in block 234 and the specified voltage is less than or equal to 1300 mV is about 25%, indicating that the margin corresponding to the word line 64 in the block 236 is greater than the tolerance corresponding to the word line 64 in the block 234 on the whole. The greater the margin, the smaller the degeneration degree at erased state is. It can be seen that the degradation degree at erased state of the word line 64 in the block 236 is smaller, that is, the crosstalk of the word line 64 in the erased state in the block 236 is lower, and the reliability of the memory is higher. FIG. 14 and FIG. 15 prove that the programming method provided by the embodiment of the present disclosure can make the memory more reliable.

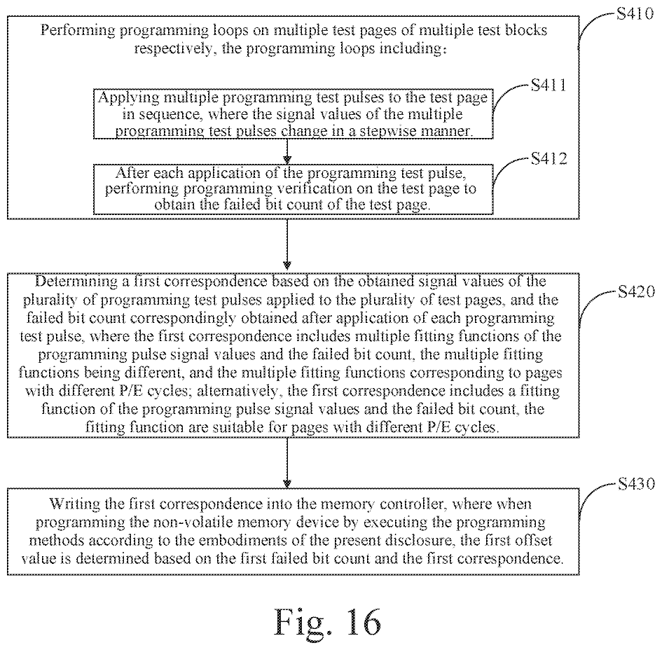

FIG. 16 illustrates a schematic flowchart of a method for fabricating a memory system according to an embodiment of the present disclosure. As shown in FIG. 16, the fabrication method includes the following steps:
S410: performing programming loops on multiple test pages of multiple test blocks respectively, the programming loops include:
S411: applying multiple programming test pulses to the test page in sequence, where the signal values of the multiple programming test pulses change in a stepwise manner; and
S412: after application of each programming test pulse, performing programming verification on the test page to obtain the failed bit count of the test page;

The fabrication method further includes:
S420: determining a first correspondence based on the obtained signal values of the plurality of programming test pulses applied to the plurality of test pages, and the failed bit count correspondingly obtained after application of each programming test pulse, where the first correspondence includes multiple fitting functions of the programming pulse signal values and the failed bit count, the multiple fitting functions being different, and the multiple fitting functions corresponding to pages with different P/E cycles; in some embodiments, the first correspondence includes a fitting function of the programming pulse signal values and the failed bit count, the fitting function being suitable for pages with different P/E cycles; and
S430: writing the first correspondence into the memory controller, where when programming the non-volatile memory device by executing the programming methods according to the embodiments of the present disclosure, the first offset value is determined based on the first failed bit count and the first correspondence.

In some embodiments, the above-described fabrication method may be completed after the structure of the non-volatile memory device is fabricated and before the memory system is packaged and shipped from the factory.

In some embodiments, the fabrication method of the memory system further includes the following steps: applying programming test pulses with the same signal value to each test page in the same test block; obtaining the gate signal value and threshold signal value of each memory cell in the test page; determining the characteristic signal value of the test page based on the gate signal value and the threshold signal value of each memory cell in the test page; obtaining the characteristic signal value of each test page in the block to determine the second correspondence, where the second correspondence is used to indicate the positional relationship between the second offset value and the second page; writing the second correspondence into the memory controller, where when the programming method according to the embodiment of the present disclosure is performed to program the non-volatile memory device, the second offset value of the second page is determined based on the positional relationship between the second page and the first page and the second correspondence.

In some embodiments, the fabrication method of the memory further includes the following steps: determining the first test signal value of the first programming test pulse for a plurality of test pages of the plurality of test blocks; the step of determining the first test signal value of the first programming test pulse includes: applying the first programming test pulse and the programming verification pulse to the test page to obtain the first test failed bit count of the test page; when the first test failed bit count is greater than the target failed bit count, applying a second programming test pulse and a programming verification pulse to the test page to obtain the second test failed bit count of the test page, where the signal value of the second programming test pulse is greater than the signal value of the first programming test pulse; when the second test failed bit count is less than or equal to the target failed bit count, determining that the signal value of the first programming test pulse is the first test signal value of the first programming test pulse of the test page; and determining the first signal value of the first programming pulse based on the first test signal value of the plurality of first programming test pulses for the plurality of test pages of the plurality of test blocks.

The first signal value of the first programming pulse is written into the memory controller, wherein the stored first signal value can be directly obtained when the nonvolatile memory device is programmed by performing the programming method according to various embodiments of the present disclosure.

With the fabrication method of the memory as described above, the first correspondence, the second correspondence and/or the first signal value of the first programming pulse are written into the memory controller or the non-volatile memory device, and may be directly invoked during programming, thereby saving programming time.

The forgoing descriptions are only specific embodiments of the present disclosure, but the scope of protection of the present disclosure is not limited thereto. Alterations or replacements within the technical scope of the present disclosure may be readily conceived by a person skilled in the art, which shall fall within the scope of protection of the present disclosure. Therefore, the scope of protection of the present disclosure should be defined only by the scope of protection of the claims.

What is claimed is:

1. A programming method for a non-volatile memory device, wherein the non-volatile memory device comprises a plurality of pages, each of the pages comprises a plurality of single-level cells, and the programming method comprises:
performing a programming operation on a first page of the plurality of pages using a signal comprising a first programming pulse, a programming verification pulse, and a second programming pulse, wherein:
the first programming pulse is a start programming pulse;
a second signal value of the second programming pulse is greater than a first signal value of the first programming pulse; and
the programming verification pulse is used to obtain a failed bit count of the first page after application of the first programming pulse and before application of the second programming pulse; and
performing a programming operation on a second page of the plurality of pages using only a third programming pulse, wherein a third signal value of the third programming pulse is determined based at least on the first signal value and the failed bit count.

2. The programming method for the non-volatile memory device according to claim 1, wherein each of the first programming pulse, the second programming pulse, and the third programming pulse is one voltage pulse signal.

3. The programming method for the non-volatile memory device according to claim 1, wherein a number of the first page is one and a number of the second page is greater than or equal to 2.

4. The programming method for the non-volatile memory device according to claim 1, wherein the third signal value of the third programming pulse is equal to a sum of the first signal value and a first offset value, wherein:
the first offset value is a difference between a first target programming pulse signal value of the first page and the first signal value;
a second target programming pulse signal value of the second page is equal to the first target programming pulse signal value; and
the first offset value is obtained based on the failed bit count of the first page.

5. The programming method for the non-volatile memory device according to claim 1, wherein the third signal value of the third programming pulse is determined based on the first signal value, the failed bit count, and a positional relationship of the second page relative to the first page.

6. The programming method for the non-volatile memory device according to claim 5, wherein the third signal value of the third programming pulse is equal to a sum of the first signal value, a first offset value, and a second offset value, wherein:
the first offset value is obtained based on the failed bit count of the first page; and
the second offset value is obtained based on the positional relationship of the second page relative to the first page.

7. The programming method for the non-volatile memory device according to claim 4, wherein the first offset value is obtained based on the failed bit count of the first page and a first correspondence, wherein:
the first correspondence comprises a plurality of fitting functions of the programming pulse signal values and the failed bit count, the plurality of fitting functions being different, and the plurality of fitting functions corresponding to pages with different P/E cycles; or
the first correspondence comprises a fitting function of the programming pulse signal values and the failed bit count, and the fitting function being suitable for pages with different P/E cycles.

8. The programming method for the non-volatile memory device according to claim 6, wherein the second offset value is obtained based on a position of the second page and a second correspondence, wherein the second correspondence is used to indicate the relationship between the second offset value and the position of the second page.

9. The programming method for the non-volatile memory device according to claim 1, after the programming operation is performed on the second page of the plurality of pages using only the third programming pulse, the programming method further comprises:
performing programming verification on the second page.

10. A non-volatile memory device, comprising:
an array of memory cells comprising a plurality of pages, each of the pages comprising a plurality of single-level cells;
peripheral circuit coupled to the array of memory cells, the peripheral circuit being configured to:
perform a programming operation on a first page of the plurality of pages using a signal comprising a first programming pulse, a programming verification pulse, and a second programming pulse, wherein the first programming pulse is a start programming pulse and a second signal value of the second programming pulse is greater than a first signal value of the first programming pulse, and the programming verification pulse is used to obtain a failed bit count of the first page after application of the first programming pulse and before application of the second programming pulse; and
perform a programming operation on a second page of the plurality of pages using only a third programming pulse, wherein a third signal value of the third programming pulse is determined based at least on the first signal value and the failed bit count.

11. The non-volatile memory device according to claim 10, wherein each of the first programming pulse, the second programming pulse, and the third programming pulse is one voltage pulse signal.

12. The non-volatile memory device according to claim 10, wherein a number of the first page is one and a number of the second page is greater than or equal to 2.

13. The non-volatile memory device according to claim 10, wherein the third signal value of the third programming pulse is equal to a sum of the first signal value and a first offset value, wherein:
the first offset value is a difference between a first target programming pulse signal value of the first page and the first signal value;
a second target programming pulse signal value of the second page is equal to the first target programming pulse signal value; and
the first offset value is obtained based on the failed bit count of the first page.

14. The non-volatile memory device according to claim 10, wherein the third signal value of the third programming pulse is determined based on the first signal value, the failed bit count, and a positional relationship of the second page relative to the first page.

15. The non-volatile memory device according to claim 14, wherein the third signal value of the third programming pulse is equal to a sum of the first signal value, a first offset value, and a second offset value, wherein:
the first offset value is obtained based on the failed bit count of the first page; and
the second offset value is obtained based on a position of the second page relative to the first page.

16. The non-volatile memory device according to claim 13, wherein the first offset value is obtained based on the failed bit count of the first page and a first correspondence, wherein:
the first correspondence comprises a plurality of fitting functions of the programming pulse signal values and the failed bit count, the plurality of fitting functions being different, and the plurality of fitting functions corresponding to pages with different P/E cycles; or
the first correspondence comprises a fitting function of the programming pulse signal values and the failed bit count, and the fitting function being suitable for pages with different P/E cycles.

17. The non-volatile memory device according to claim 15, wherein the second offset value is obtained based on a position of the second page and a second correspondence,
wherein the second correspondence is used to indicate a relationship between the second offset value and the position of the second page.

18. The non-volatile memory device according to claim 10, wherein the peripheral circuit is configured to:
perform programming verification on the second page.

19. A memory system, comprising:
one or more non-volatile memory devices; and
a memory controller coupled to the non-volatile memory device and configured to control the non-volatile memory device,
wherein each of the one or more non-volatile memory devices comprises:
an array of memory cells comprising a plurality of pages, each of the pages comprising a plurality of single-level cells;
peripheral circuit coupled to the array of memory cells, the peripheral circuit being configured to:
perform a programming operation on a first page of the plurality of pages using a signal comprising a first programming pulse, a programming verification pulse, and a second programming pulse, wherein the first programming pulse is a start programming pulse and a second signal value of the second programming pulse is greater than a first signal value of the first programming pulse, and the programming verification pulse is used to obtain a failed bit count of the first page after application of the first programming pulse and before application of the second programming pulse; and
perform a programming operation on a second page of the plurality of pages using only a third programming pulse, wherein a third signal value of the third programming pulse is determined based at least on the first signal value and the failed bit count.

20. The memory system according to claim 19, wherein:
the non-volatile memory device comprises a plurality of pages, each of the pages comprising a plurality of single-level cells;
the non-volatile memory device is configured to perform a programming operation on a first page of the plurality of pages using a first programming pulse, a programming verification pulse, and a second programming pulse in sequence; wherein the first programming pulse is a start programming pulse and a second signal value of the second programming pulse is greater than a first signal value of the first programming pulse, and the programming verification pulse is used to obtain a failed bit count of the first page after application of the first programming pulse and before application of the second programming pulse;
the memory controller is configured to determine a third signal value of a third programming pulse applied to a second page based on the first signal value and the failed bit count, wherein the second page is different from the first page; and
the non-volatile memory device is configured to perform a programming operation on the second page using only the third programming pulse.
